(19) United States
(12) Patent Application Publication
(10) Pub. No.: US 2015/0048827 A1
(43) Pub. Date: Feb. 19, 2015

(54) GRADIENT COIL SUPPORTING IMPLEMENT AND MAGNETIC RESONANCE IMAGING APPARATUS

(71) Applicants: KABUSHIKI KAISHA TOSHIBA, Tokyo (JP); TOSHIBA MEDICAL SYSTEMS CORPORATION, Otawara-Shi (JP)

(72) Inventors: Kota WATANABE, Otawara-Shi (JP); Hiromitsu TAKAMORI, Otawara-Shi (JP)

(21) Appl. No.: 14/457,790

(22) Filed: Aug. 12, 2014

(30) Foreign Application Priority Data
Aug. 19, 2013 (JP) 2013169958

(51) Int. Cl. G01R 33/385; G01R 33/54

(52) U.S. Cl. CPC G01R 33/3858; G01R 33/543
USPC 324/318

(57) ABSTRACT

In one embodiment, a gradient coil supporting implement includes three bearings and a mounting main body. At least one of the three bearings is a spherical bearing. Shafts of these bearings are fixed to a static magnetic field magnet of an MRI apparatus. One end side of the mounting main body is fixed to an outer periphery side of an end face of the static magnetic field magnet, at one position via one of the bearings. The other end side of the mounting main body is fixed to an inner periphery side of the end face of the static magnetic field magnet, at two positions via the other two bearings. The mounting main body supports the gradient magnetic field coil unit (installed inside the static magnetic field magnet) in the horizontal direction by being partially made in contact with the gradient magnetic field coil unit.

### CROSS-REFERENCE TO RELATED APPLICATION

This application is based upon and claims the benefit of priority from Japanese Patent Application No. 2013-169958 filed on Aug. 19, 2013;

The entire contents of which are incorporated herein by reference.

### BACKGROUND OF THE INVENTION

1. Field of the Invention

Embodiments described herein relate generally to a gradient coil supporting implement and a magnetic resonance imaging apparatus.

2. Description of the Related Art

MRI is an imaging method which magnetically excites nuclear spin of an object (a patient) placed in a static magnetic field with an RF pulse having the Larmor frequency and reconstructs an image on the basis of MR signals generated due to the excitation. The aforementioned MRI means magnetic resonance imaging, the RF pulse means a radio frequency pulse, and the MR signal means a nuclear magnetic resonance signal.

A gantry of an MRI apparatus is composed by disposing a cylindrical gradient magnetic field coil unit inside a cylindrical static magnetic field magnet and disposing a cylindrical RF coil unit inside the gradient magnetic field coil unit, for example. The gradient magnetic field coil unit applies gradient magnetic fields, which give positional information to MR signals, to an imaging region. The RF coil unit transmits the above RF pulses to the imaging region.

The static magnetic field magnet is included inside a cylindrical vacuum container in the case of being composed as, for example, a cylindrical superconductive magnet. This vacuum container is formed by welding an inner cylinder, an outer cylinder and two (ambilateral) circular end plates together, for example. In conventional technology, the gradient magnetic field coil unit is fixed in the horizontal direction by, for example, ambilateral supporting members respectively fixed to both end plates of the vacuum container of the static magnetic field magnet.

Here, in MRI apparatuses of recent years, gradient magnetic fields are rapidly switched in accordance with speed-up of imaging technology. Therefore, the gradient magnetic field coil unit vibrates due to mutual interaction between the electric currents flowing gradient magnetic field coils inside the gradient magnetic field coil unit and the static magnetic field. Because the end plates of the static magnetic field magnet have low rigidity, the static magnetic field magnet vibrates with high resonance magnification to become a noise source if the vibration of the gradient magnetic field coil unit propagates.

Then, in order to reduce sound noise caused by solid propagation, a technology to reduce vibration transfer rate to the static magnetic field magnet by supporting the gradient magnetic field coil unit via vibration-proof rubber is known (see, for example, Japanese Patent Application Laid-open (KOKAI) Publication No. 2005-245775 and Japanese Patent Application Laid-open (KOKAI) Publication No. 2007-190200).

In the vacuum container of the static magnetic field magnet, weak parts in terms of rigidity are, for example, the welded part between the inner cylinder and the end plates, the welded part between the outer cylinder and the end plates, or the like.

Because each part such as the end plate of the vacuum container of the conventional technology has sufficient thickness that gives enough rigidity, the vacuum container of the conventional technology has no possibility of being damaged when large load is added to the end plates thereof during transportation or earthquake.

On the other hand, weight reduction of the vacuum container by thinning the end plates or the like is desired. However, the rigidity of the vacuum container is lowered if its weight is reduced. That is, in order to achieve weight reduction, a technology to prevent a vacuum container from being damaged even if a large load is applied to a thin-walled vacuum container.

In order to achieve that, it is preferable to suppress propagation of the vibration of the gradient magnetic field coil unit further than the conventional technology.

Therefore, in MRI, a novel technology to prevent vibration of a gradient magnetic field coil unit from propagating to the side of a static magnetic field magnet has been desired.

### BRIEF DESCRIPTION OF THE DRAWINGS

In the accompanying drawings:

FIG. 1 is a schematic planimetric diagram of the gradient coil supporting implement of the first embodiment;

FIG. 2 is a schematic oblique drawing showing an example of the overall structure of a spherical bearing;

FIG. 3 is a schematic cross-sectional diagram showing an example of the cross-sectional structure of the spherical bearing along the diameter of its outer ring;

FIG. 4 is a schematic planimetric diagram of the spherical bearing observed from the direction of the arrow in FIG. 3;

FIG. 5 is a schematic diagram showing an example of the structure of the shaft of the spherical bearing;

FIG. 6 is a schematic exploded perspective view showing an example of the outer ring of the spherical bearing;

FIG. 7 is a schematic oblique drawing magnifying the lower edge of the first supporting member in FIG. 1;

FIG. 8 is a schematic oblique drawing showing an example of the structure of the bearing fixing tool FX;

FIG. 9 is a schematic oblique drawing showing an example of methods of fixing the spherical bearing to the plate;

FIG. 10 is a schematic oblique drawing showing the state in which the lower edge of the first supporting member is fixed to the plate with two of the bearing fixing tools and the spherical bearing;

FIG. 11 is a schematic oblique drawing showing the connecting part of the first supporting member and the second supporting member in the gradient coil supporting implement of the first embodiment;

FIG. 12 is a schematic planimetric diagram of the respective first supporting members respectively fixed to end faces of the static magnetic field magnet in the entrance side and the deep side of the gantry;

FIG. 13 is a schematic oblique drawing magnifying the part of the second supporting member in FIG. 11;

FIG. 14 is a schematic oblique drawing showing the state in which the third supporting member is separated from the first supporting member and the second supporting member;

FIG. 15 is a schematic oblique drawing showing the state in which the third supporting member has been fixed to the first supporting member and the second supporting member from the state of FIG. 14 and then the RF coil unit is fixed on the third supporting member;

FIG. 16 is a block diagram showing an example of the overall structure of the MRI apparatus of the first embodiment;

FIG. 17 is a flowchart illustrating an example of a flow of a process performed by the MRI apparatus of the first embodiment;

FIG. 18 is a schematic cross-sectional diagram showing an example of the structure of the third supporting member of the gradient coil supporting implement in the second embodiment;

FIG. 19 is a schematic exploded perspective view of the connecting part between the third supporting member and the RF coil unit in FIG. 18;

FIG. 20 is a schematic planimetric diagram of the gantry of the MRI apparatus of the third embodiment;

FIG. 21 is a schematic cross-sectional diagram showing an example of the second supporting member of the gradient coil supporting implement in the third embodiment;

FIG. 22 is a schematic cross-sectional diagram showing an example of the structure of the gradient coil supporting implement of the modified version of the third embodiment; and

FIG. 23 is a schematic planimetric diagram showing an example of the structure of the gradient coil supporting implement of the modified version of the first embodiment.

### DETAILED DESCRIPTION

Hereinafter, examples of aspects which embodiments of the present invention can take will be explained per aspect.

(1) According to one embodiment, a gradient coil supporting implement supports a gradient magnetic field coil unit installed inside a static magnetic field magnet in an MRI apparatus, and includes three bearings and a mounting main body.

A shaft of each of the three bearings is fixed to an end face of the static magnetic field magnet, and at least one of the three bearings is a spherical bearing.

The mounting main body is fixed to the end face of the static magnetic field magnet via the three bearings, and supports the gradient magnetic field coil unit at least in the horizontal direction by being partially made in contact with the gradient magnetic field coil unit. One end side of the mounting main body is fixed to an outer periphery side of the end face of the static magnetic field magnet, at one position via one of the three bearings. The other end side of the mounting main body is fixed to an inner periphery side of the end face of the static magnetic field magnet, at two positions via two of the three bearings.

(2) In another embodiment, an MRI apparatus includes a static magnetic field magnet, a gradient magnetic field coil unit, the gradient coil supporting implement of the above (1), an RF coil unit and a control device.

The static magnetic field magnet applies a static magnetic field to an imaging space.

The gradient magnetic field coil unit is installed at an inner side of the static magnetic field magnet, and applies a gradient magnetic field to an imaging region.

The gradient coil supporting implement supports the gradient magnetic field coil unit.

The RF coil unit transmits an RF pulse for causing nuclear magnetic resonance to the imaging region.

The control device performs a pulse sequence, in which MR signals from an object in the imaging region are acquired, by controlling the gradient magnetic field coil unit and the RF coil unit, and reconstructs image data on the basis of the MR signals.

Hereinafter, some examples of gradient coil supporting implements and MRI apparatuses according to embodiments of the present invention will be described with reference to the accompanying drawings. Note that the same reference numbers are given for identical components in each figure, and overlapping explanation is abbreviated.

### The First Embodiment

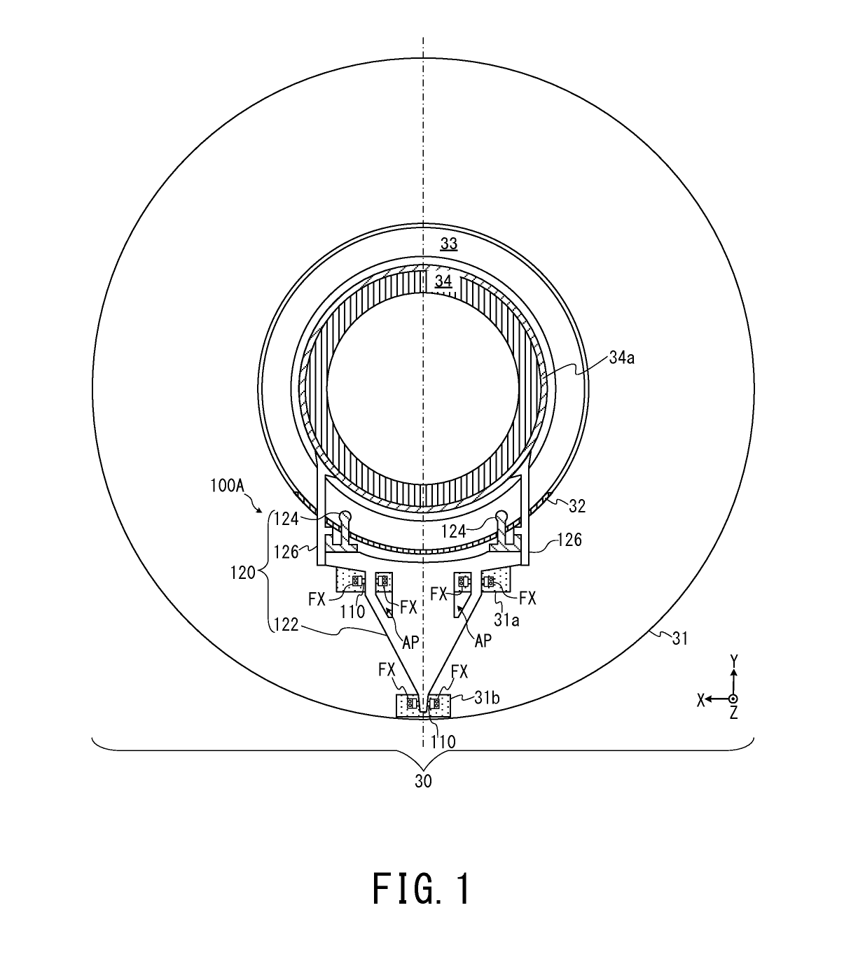

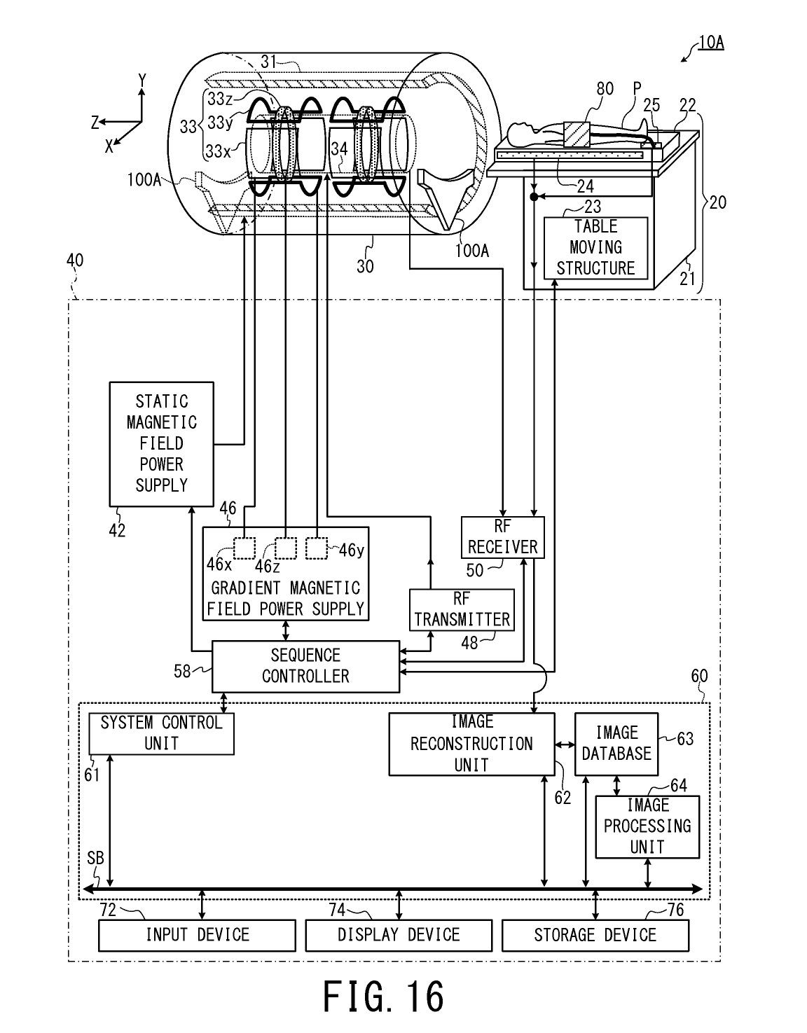

FIG. 1 is a schematic planimetric diagram of a gradient coil supporting implement 100A of the first embodiment. As an example here, the gradient coil supporting implement 100A is interpreted as a part of the gantry 30 of the MRI apparatus 10A (see later-descried FIG. 16). However, the gradient coil supporting implement 100A may be interpreted as a unit independent from the MRI apparatus 10A (this point holds true for the second embodiment and the following embodiments).

As shown in FIG. 1, the gantry 30 includes a cylindrical static magnetic field magnet 31, a vibration-proof sheet 32 (corresponding to the region covered with vertical lines in FIG. 1), a cylindrical gradient magnetic field coil unit 33 and a cylindrical RF coil unit 34.

The gradient magnetic field coil unit 33 is placed on the vibration-proof sheet 32 that is laid on the inner side of the static magnetic field magnet 31. Thus, as an example here, the weight of the gradient magnetic field coil unit 33 is supported by the vacuum container of the static magnetic field magnet 31.

The RF coil unit 34 is installed at the inner side of the gradient magnetic field coil unit 33. The RF coil unit 34 is installed in a state floating from the gradient magnetic field coil unit 33, and the weight of the RF coil unit 34 is supported by two gradient coil supporting implements 100A.

The inner side of the RF coil unit 34 (i.e. the bore of the gantry) becomes an imaging space.

The RF coil unit 34 corresponds to a combination region of the annular region covered with left-downward slant lines and the annular region covered with vertical lines in FIG. 1, and the outer peripheral side of its container is formed as a protrusion part 34a corresponding to the region covered with left-downward slant lines.

The axial length (the length in the Z axis direction in FIG. 1) of the protrusion part 34a is longer than the rest of the container of the RF coil unit 34.

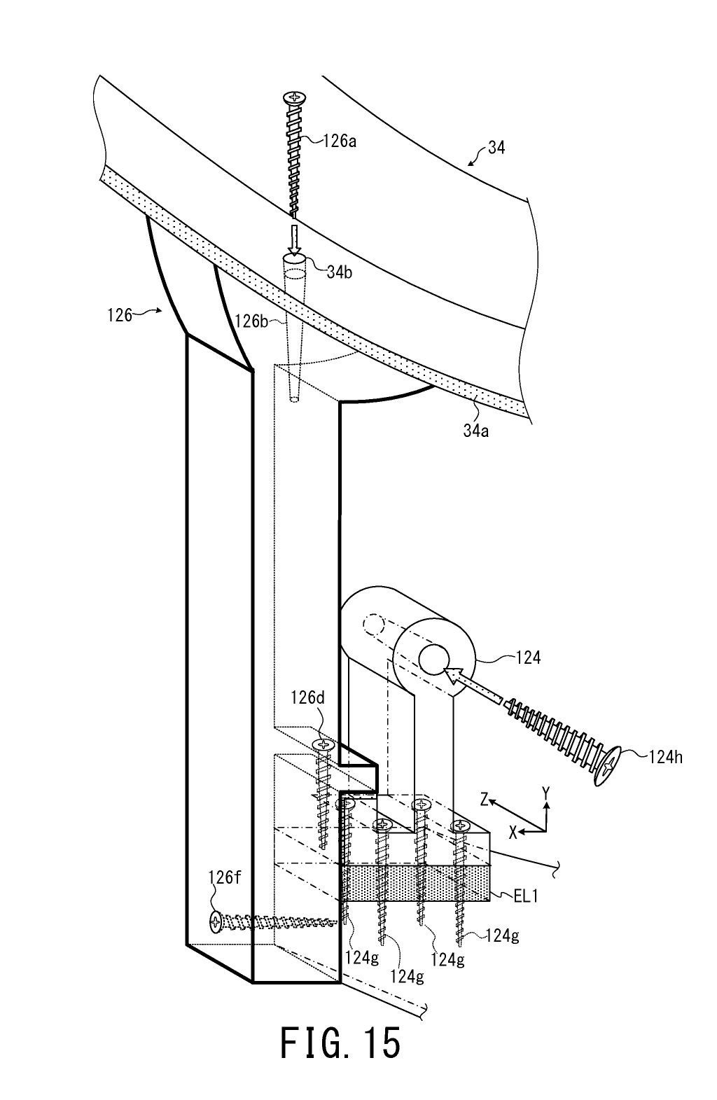

As described later with FIG. 15, screw holes 34b are formed on this protrusion part 34a in order for the RF coil unit 34 to be fixed to the third supporting members 126 of the gradient coil supporting implements 100A.

In this specification, the X axis, the Y axis and the Z axis are assumed to be those of the apparatus coordinate system unless otherwise specifically noted. As an example here, the apparatus coordinate system, whose X axis, Y axis and Z axis are perpendicular to each other, is defined as follows.

First, the Y axis direction is defined as the vertical direction. The gantry 30 is disposed in such a manner that each axis direction of the static magnetic field magnet 31, gradient magnetic field coil unit 33 and the RF coil unit 34 accords with the Y axis direction. The X axis direction is the direction perpendicular to these Y axis direction and Z axis direction. Thus, FIG. 1 is a schematic planimetric diagram observed from the Z axis direction.

The static magnetic field magnet 31 is constituted by, for example, containing a non-illustrated superconductive coil in a cylindrical vacuum container. The vacuum container is constituted by, for example, welding an inner cylinder, an outer cylinder and two annular end plates each other. These inner cylinder, outer cylinder and annular end plates are made of high-strength metal material such as stainless. Two sets of the plates 31a and 31b made of stainless or the like are respectively welded on both end faces of (the vacuum container of) the static magnetic field magnet 31.

The gantry 30 includes two gradient coil supporting implements 100A (only one of them is shown in FIG. 1). That is, each of the two gradient coil supporting implements 100A is respectively fixed to each end face of the static magnetic field magnet 31 in the entrance side and the deep side of the cylindrical gantry 30.

The above end faces indicate the annular planes of both sides of the cylindrical static magnetic field magnet 31, i.e. the surfaces of the annular end plates. Each end face of the static magnetic field magnet 31 is flat in parallel with the X-Y plane.

The gradient coil supporting implement 100A supports (holds) the gradient magnetic field coil unit 33 in such a manner that the gradient magnetic field coil unit 33 never moves in the Z axis direction (i.e. horizontal direction). In addition, two gradient coil supporting implements 100A support and fix the RF coil unit 34.

Each gradient coil supporting implement 100A includes three spherical bearings 110, six bearing fixing tools FX and a mounting main body 120.

The mounting main body 120 is formed in such a manner that (a) its thickness in the Z axis direction in the installed state shown in FIG. 1 becomes uniform except the parts of the later-described screw holes and (b) it has a line-symmetrical structure relative to the Y-Z plane (relative to the vertical chain line in FIG. 1).

The mounting main body 120 includes a first supporting member (bracket) 122, two second supporting members 124 (corresponding to the regions covered with right-downward slant lines in FIG. 1) respectively fixed to the upper end of the first supporting member 122, and two third supporting members 126 respectively fixed to both sides of the upper end of the first supporting member 122.

Although the first supporting member 122, the second supporting members 124 and the third supporting members 126 are made of, for example, stainless or the like, these may be made of titanium or aluminum. It is desirable to form these members from (a) high strength metal of nonmagnetic material that is hard to rust or (b) high strength resin such as FRP (Fiber Reinforced Plastic).

The above “high strength” means thickness and rigidity that is enough to keep its shape undeformed at least under the weight of the RF coil unit 34. Note that, the above “high strength” means thickness and rigidity that is enough to keep its shape undeformed at least under the total weight of the RF coil unit 34 and the gradient magnetic field coil unit 33′, in the case of the third embodiment in which the gradient magnetic field coil unit 33′ is also supported in a floating state.

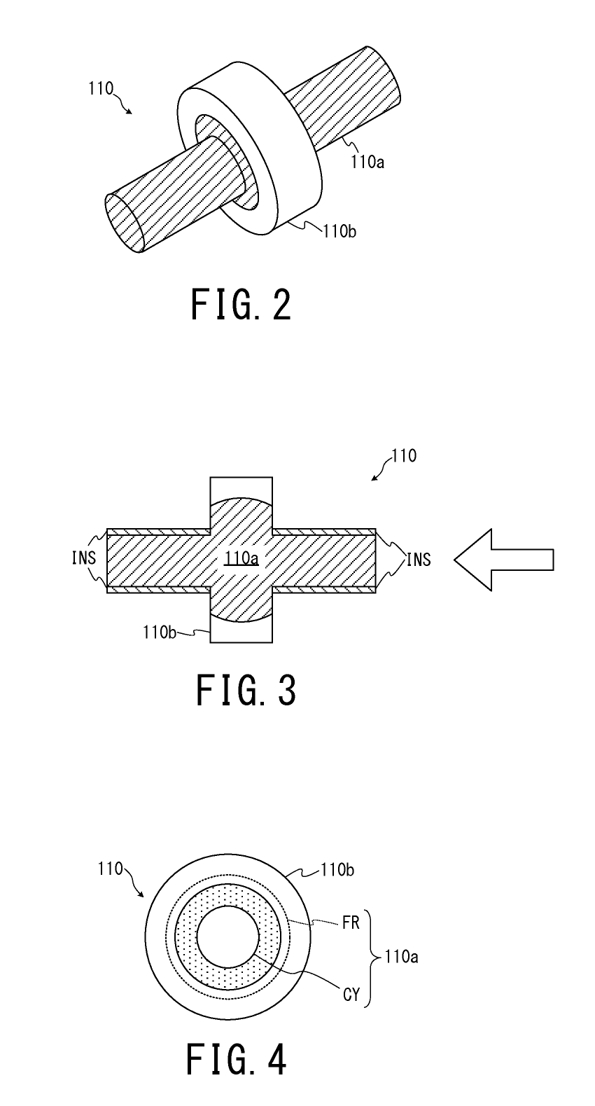

Three points of the first supporting member 122 are respectively fixed to the plates 31a and 31b welded on the end plate of the static magnetic field magnet 31, with the three spherical bearings 110. A shaft 110a (see later described FIG. 2 to FIG. 4) of each of the spherical bearings 110 is fixed to the plate 31a or 31b with two bearing fixing tools FX.

It is preferable that the first supporting member 122 is fixed to each end face of the static magnetic field magnet 31 at three points like the present embodiment. This is because each end face of the static magnetic field magnet 31 is planar and it is preferable that the respective fixation points of the first supporting member 122 are positioned in the same plane.

More specifically, in the case of the three-point fixation, these three fixation points are positioned in the same plane inevitably. However, in the case of the four-point fixation, it is not necessarily easy to position these four fixation points perfectly in the same plane. If these four fixation points are not positioned in the same plane, the load of installing the gradient coil supporting implements 100A to both end faces of the static magnetic field magnet 31 becomes large and local stress easily occurs.

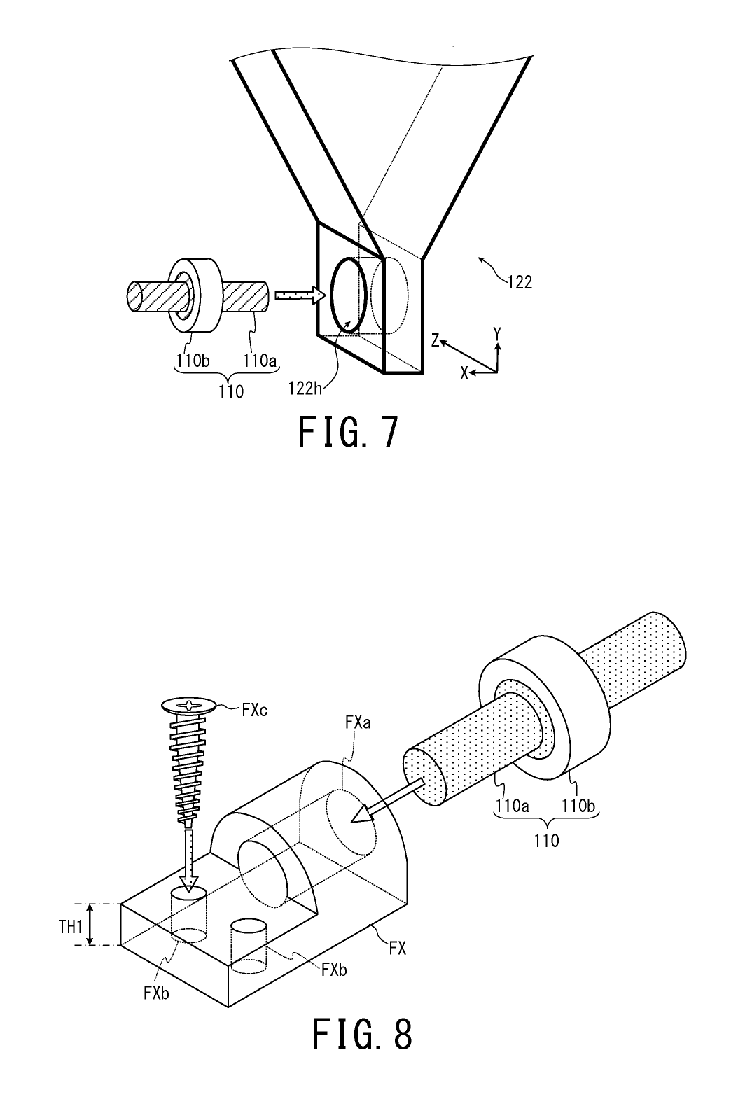

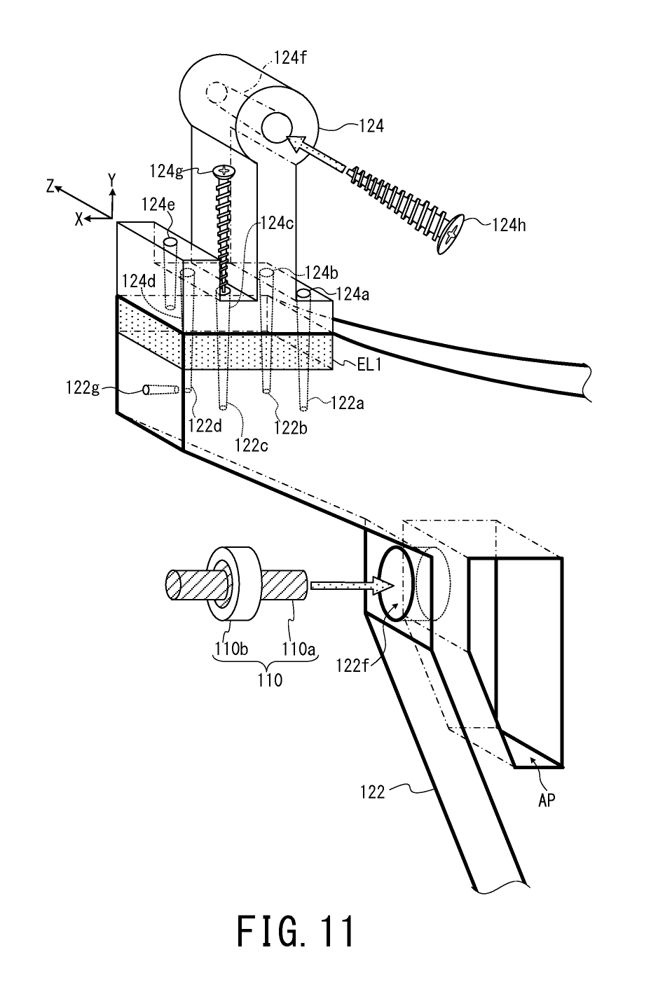

The first supporting member 122 is formed in a line symmetrical shape so as to be tapered toward its one end side (corresponding to the outer peripheral side of the static magnetic field magnet 31 in FIG. 1). The first supporting member 122 includes totally three insertion holes 122f and 122h (see later-described FIG. 7 and FIG. 11) into which three spherical bearings 110 are respectively inserted in the X axis direction in FIG. 1.

In addition, the first supporting member 122 includes two openings AP. These two opening AP respectively function as work space, in time of fixing two spherical bearing 110 respectively inserted into two insertion holes 122f with the bearing fixing tools FX. Here, these two insertion holes 122f are respectively formed at two other end side of the first supporting member 122 (the side of the second supporting members 124, i.e. the inner peripheral side of the static magnetic field magnet 31 in FIG. 1).

FIG. 2 is a schematic oblique drawing showing an example of the overall structure of the spherical bearing 110.

FIG. 3 is a schematic cross-sectional diagram showing an example of the cross-sectional structure of the spherical bearing 110 along the diameter of its outer ring 110b.

FIG. 4 is a schematic planimetric diagram of the spherical bearing 110 observed from the direction of the arrow in FIG. 3.

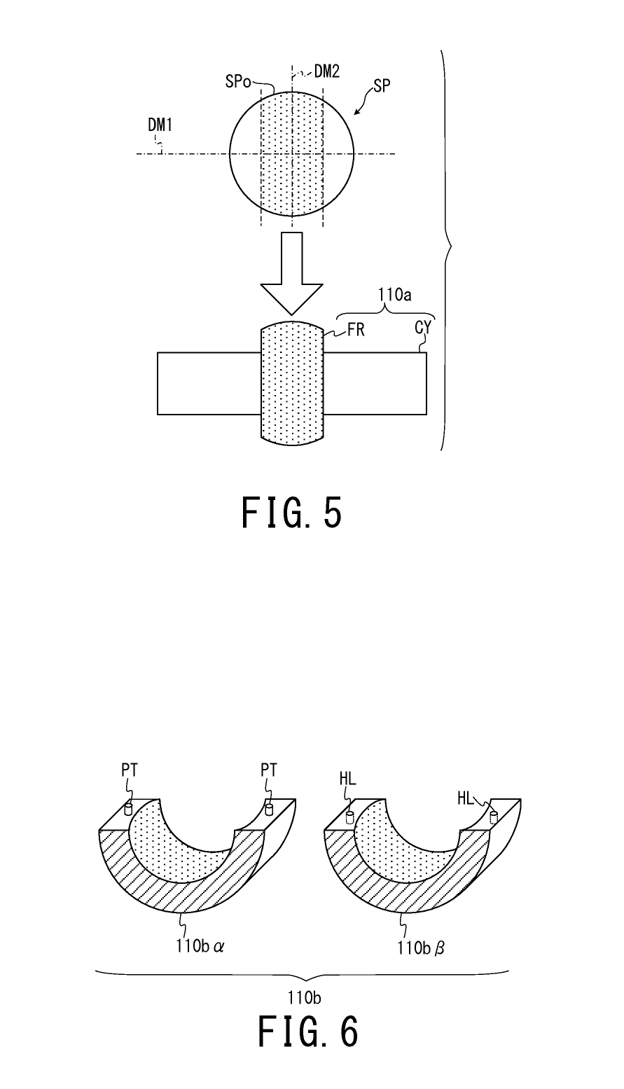

FIG. 5 is a schematic diagram showing an example of the structure of the shaft 110a of the spherical bearing 110.

FIG. 6 is a schematic exploded perspective view showing an example of the outer ring 110b of the spherical bearing 110.

Hereinafter, the structure of the spherical bearing 110 will be explained with reference to FIG. 2 to FIG. 6.

As shown in FIG. 2 and FIG. 3, the spherical bearing 110 is composed of the shaft 110a (corresponding to the shaded region) and the outer ring 110b (corresponding to the rest area excluding the shaded region).

As shown in FIG. 4, the shaft 110a is composed of a cylindrical rod CY and a flange FR. In FIG. 4, the annular dashed line indicates the maximum diameter of the flange FR, and the part with this maximum diameter of the flange FR is invisible from the outside because it hides inside the outer ring 110b. In FIG. 4, the annular region shown with hatching is an exposed part of the flange FR (the part that is not hidden by the outer ring 110b).

The shape of the above shaft 110a is as follows.

More specifically, as shown in FIG. 5, consider a diameter DM1 of a sphere SP and a diameter DM2 which is orthogonal to the diameter DM1. Here, the sphere SP is divided into three portions line-symmetrically about the diameter DM2, in such a manner that the normal line of the two cutting sections accords with the diameter DM1. In this case, these two cutting sections (transverse sections) become circular.

The central portion SPo of the trisected sphere SP is the region shown with hatching in the upper part of FIG. 5. The central portion SPo becomes the flange FR of the shaft 110a.

That is, a cylindrical hole is formed in the center of the central portion SPo in such a manner that the axis direction of the hole accords with the diameter DM1 of the original sphere SP. Then, the shaft 110a is formed by interdigitating and welding the cylindrical rod CY with the hole formed in the central portion SPo. The lower part of FIG. 5 is a schematic planimetric diagram of the shaft 110a formed in the above manner.

Next, the shape of the outer ring 110b will be explained with FIG. 6.

The outer ring 110b is approximately in a ring shape, and its surface is composed of the following four; i.e. two annular end faces, an outer peripheral surface like a side surface of a cylinder and a spherically formed inner surface. The inner surface of the outer ring 110b is spherically chamfered so as to closely adhere to the spherically chamfered outer peripheral surface of the flange FR.

The above structure can be formed by combining the first outer ring section 110bα and the second outer ring section 110bβ, each of which are in the form of a bisected outer ring 110b, as shown in FIG. 6, for example.

In the first outer ring section 110bα and the second outer ring section 110bβ shown in FIG. 6, the shaded regions correspond to the end face of the outer ring 110b and the hatching regions correspond to the inner surface of the outer ring 110b.

The first outer ring section 110bα includes two cylindrical protrusions PT respectively formed on the two surfaces welded to the second outer ring section 110bβ. The second outer ring section 110bβ includes two cylindrical fixing holes HL, which are respectively interdigitated with two protrusions PT, on the two surfaces welded to the first outer ring section 110bα.

Under the state in which the spherical surface of the flange FR of the shaft 110a is closely adhered to the inner surface of the first outer ring section 110bα, the spherical bearing 110 is formed by covering the second outer ring section 110bβ from above it so as to interdigitate each protrusion PT with each fixing hole HL, for example.

At this time, the first outer ring section 110bα and the second outer ring section 110bβ may be connected with each other by using, for example, adhesion bond in such a manner that any change does not occur on the surface of the shaft 110a.

In the above manner, the spherical bearing 110 whose structure is shown in FIG. 2 to FIG. 4 is formed. In such structure, the shaft 110a can move in an arbitrary direction, because the inner surface of the outer ring 110b and the flange FR are formed to be brought into spherical surface contact with each other.

Here, it is preferable that at least a part of the spherical bearing 110 is formed of an insulator so as to insulate between the static magnetic field magnet 31 and the mounting main body 120.

As an example here, as shown in FIG. 3, a cylindrical insulation sheets INS are wound around the outer periphery side of the cylindrical rod CY of the shaft 110a.

In addition, because a considerable weight is applied to the spherical bearing 110, all parts of the spherical bearing 110 other than the above insulation sheets INS are formed of, for example, metal such as stainless so as to have enough thickness (diameter).

It is preferable to form all parts of the spherical bearing 110 other than the above insulation sheets INS from high strength metal of nonmagnetic material.

Alternatively, the entire shaft 110a may be formed of stainless and the entire outer ring 110b may be formed of electric insulating and reinforced resin such as FRP (Fiber Reinforced Plastics).

Alternatively, the entire spherical bearing 110 may be formed of FRP if the strength of FRP is enough to support the weight of the RF coil unit 34 and so on.

In addition, it is desirable to apply nonconductive and slippery resin coating on at least one of the spherical part of the flange FR of the shaft 110a and the spherical inner surface of the outer ring 110b. This is because the mutual friction between metal parts is suppressed. As an example of such coating in the first embodiment, Teflon (Trademark) coating is applied on the spherical part of the flange FR and the inner surface of the outer ring 110b.

FIG. 7 is a schematic oblique drawing magnifying the lower edge of the first supporting member 122 in FIG. 1. As shown in FIG. 7, the first supporting member 122 has a lower edge section fixed on the plate 31b of the outer periphery side of the end face of the static magnetic field magnet 31, and a cylindrical insertion hole 122h is formed in this lower edge section. The axial direction of the insertion hole 122h accords with the X axis direction at installment.

Thus, the opening area of the insertion hole 122h in the first supporting member 122 is chamfered so as to become in parallel with the Y-Z plane. The insertion hole 122h penetrates to the opposite side in the X axis direction at installment, the diameter1 of the insertion hole 122h is equal to the diameter of the outer ring 110b of the spherical bearing 110. That is, the outer ring 110b of the spherical bearing 110 is included in the insertion hole 122h and interdigitated with the insertion hole 122h.

FIG. 8 is a schematic oblique drawing showing an example of the structure of the bearing fixing tool FX. The profile of the bearing fixing tool FX is, for example, like a shape obtained by connecting a plate with a bisected cylinder. The bearing fixing tool FX is formed of, for example, stainless or the like.

It is preferable to form the bearing fixing tool FX from nonmagnetic metal having enough strength and thickness, in the way similar to the first supporting member 122 and so on. A cylindrical storage opening FXa, through which the shaft 110a of the spherical bearing 110 is inserted, is formed on the cylindrically protruded part of the bearing fixing tool FX.

In addition, two screw holes FXb, through which screws FXc for fixing the bearing fixing tool FX to the plate 31a or 31b are inserted, are formed on the flatly formed part of the bearing fixing tool FX.

Note that, though only one screw FXc is shown in FIG. 8 in order to avoid complication, each of the bearing fixing tools FX includes two screws FXc.

The thickness TH1 of the flat part of the bearing fixing tool FX is selected in the following manner.

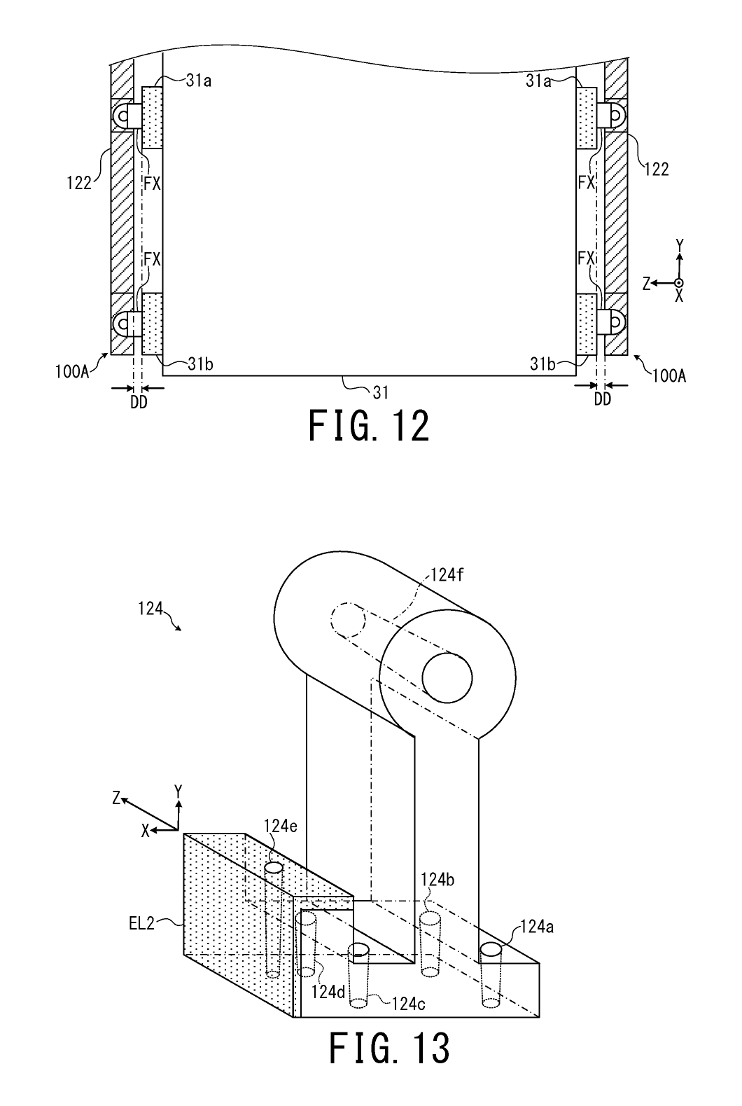

That is, the thickness TH1 is selected so as to separate the first supporting member 122 from the plates 31a and 31b by the interval DD, under the state where the first supporting member 122 is fixed to the plates 31a and 31b with the bearing fixing tools FX and the spherical bearings 110 (for details, see later-described FIG. 12).

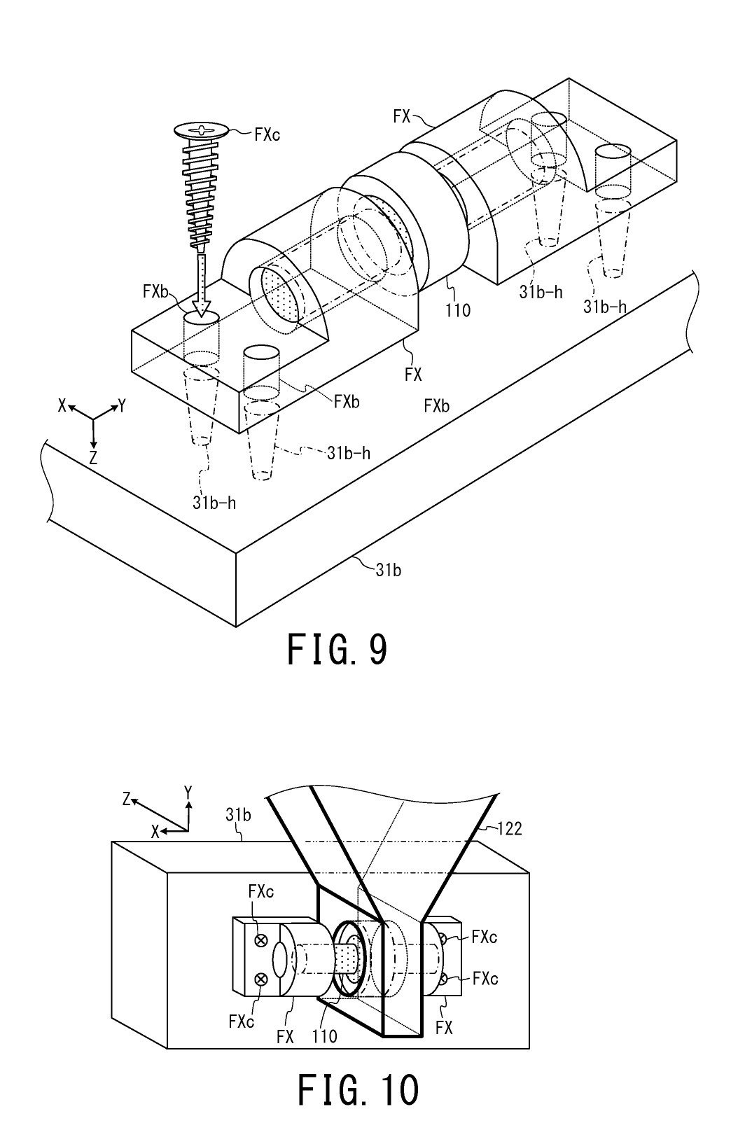

FIG. 9 is a schematic oblique drawing showing an example of methods of fixing the spherical bearing 110 to the plate 31b. For distinction in FIG. 9, the invisible outline of the bearing fixing tool FX is indicated by dashed lines, and the invisible outlines of the spherical bearing 110 and the screw holes of the plate 31b are indicated by chain lines. Note that, the first supporting member 122 is omitted in FIG. 9 in order to avoid complication.

FIG. 10 is a schematic oblique drawing showing the state in which the lower edge of the first supporting member 122 is fixed to the plate 31b with two bearing fixing tools FX and one spherical bearing 110.

For distinction in FIG. 10, the outline of the first supporting member 122 is indicated by bold lines, the hidden outline of the first supporting member 122 is indicated by dashed lines, and the hidden outline of the spherical bearing 110 is indicated by chain lines.

Hereinafter, a method of fixing the spherical bearing 110 by the bearing fixing tools FX will be explained with reference to FIG. 9 and FIG. 10.

As shown in FIG. 9, in the plate 31b, four screw holes 31b-h are formed on the positions respectively overlapping the totally four screw holes FXb of two bearing fixing tools FX.

Each of the two bearing fixing tools FX is abutted onto the plate 31b in such a manner that both sides of the cylindrical rod CY of the shaft 110a of the spherical bearing 110 are respectively included in the storage openings FXa of the two bearing fixing tools FX. At this time, positioning is performed in such a manner that each of the screw holes FXb overlaps each of the screw holes 31b-h.

Then, the two bearing fixing tools FX are tightly fixed to the plate 31b by inserting and tightening the screws FXc in the respective the screw holes FXb and 31b-h. Thereby, the lower edge section of the first supporting member 122, with which the outer ring 110b of the spherical bearing 110 is interdigitated, is fixed to the plate 31b as shown in FIG. 10. This is because the spherical bearing 110, whose cylindrical rod CY is partially included in the storage opening FXa of each of the two bearing fixing tools FX, is fixed.

Note that, the first supporting member 122 is separated from the plate 31b by the interval DD in this fixed state, as described earlier.

Here, the respective shafts 110a of the three spherical bearings 110 respectively interdigitated with three positions of the first supporting member 122 can tilt in accordance with slight inclination between the respective surfaces of the first supporting member 122 and the plates 31a, 31b, in time of fixing the first supporting member 122. Thereby, a partial stress to the first supporting member 122 does not easily occur after fixing the first supporting member 122.

In other words, the spherical inner surface of the outer ring 110 and the spherical side surface of the flange FR slide in accordance with a slight inclination between the respective surfaces of the first supporting member 122 and the plates 31a, 31b, and thereby generation of a local stress is suppressed.

FIG. 11 is a schematic oblique drawing showing the connecting part between the first supporting member 122 and the second supporting member 124 in the gradient coil supporting implement 100A of the first embodiment.

In FIG. 11, the outline of the first supporting member 122 is indicated by bold lines, the outline of the second supporting member 124 is indicated by solid lines. Invisible outlines of opening holes are indicated by dashed lines, and the rest of the invisible outlines are indicated by chain lines. Note that, the third supporting members 126 is omitted in FIG. 11 in order to avoid complication.

As shown in FIG. 11 and the aforementioned FIG. 1, the parts of the first supporting member 122 fixed to the inner periphery side (the plate 31a side) of the static magnetic field magnet 31 protrude like arms on both sides, and the two second supporting members 124 are respectively fixed to these protruded parts.

More specifically, as shown in FIG. 11, the second supporting member 124 includes four screw holes 124a, 124b, 124c and 124d having the same dimension along the direction that becomes the vertical direction (the Y Axis direction) when the gradient coil supporting implement 100A is installed. The respective openings of the four screw holes 124a to 124d are positioned in the same plane.

On the other hand, a sheet shaped or approximately rectangular parallelepiped shaped vibration-proof member EL1 is connected with the part (corresponding to the hatching region in FIG. 11) of the first supporting member 122 to which the second supporting members 124 is fixed.

The vibration-proof member EL1 is formed of elastic material such as rubber. This is so that the propagation of vibration from the gradient magnetic field coil unit 33 to the first supporting member 122 via the second supporting members 124 is prevented.

In the first supporting member 122, the screw holes 122a, 122b, 122c and 122d penetrating the above vibration-proof member EL1 are formed on the area positioned on the extended lines of the respective screw holes 124a, 124b, 124c and 124d of the second supporting members 124. The respective screw holes 122a to 122d have the same dimension.

One screw 124g is inserted and tightened in the screw holes 124c and 122c.

Although the other three screws 124g are omitted in FIG. 11 in order to avoid complication, Another screw 124g is similarly inserted and tightened in the screw holes 124a and 122a.

Similarly, another screw 124g is inserted and tightened in the screw holes 124b and 122b.

Similarly, the other screw 124g is inserted and tightened in the screw holes 124d and 122d.

The second supporting member 124 is fixed to the first supporting member 122 with these four screws 124g.

In addition, a screw hole 124e for fixing the third supporting members 126 is formed on the second supporting member 124. The direction of the screw hole 124e is the vertical direction at installment, in the way similar to the screw holes 124a to 124d.

In addition, the lateral surface of the first supporting member 122, which becomes the endmost part in the X axis direction at installment, is formed so as to become in parallel with the Y-Z plane, and the screw hole 122g for fixing the third supporting members 126 is formed on this lateral surface.

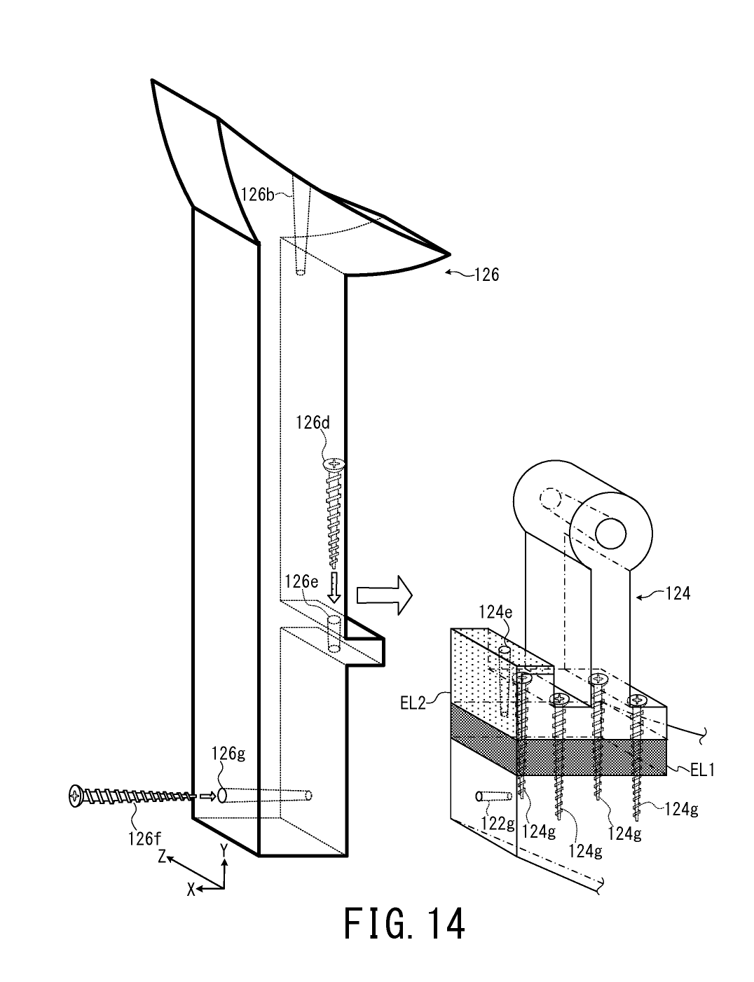

As to the fixing method of the third supporting members 126, it will be explained with the later-described FIG. 14 and FIG. 15.

The top end of the second supporting members 124 is approximately cylindrically chamfered, and the screw hole 124f is formed so as to penetrate the center of the top end. The direction of the screw hole 124f accords with the Z axis direction at installment.

A pressing screw 124h is inserted and tightened in this screw hole 124f. The end of the pressing screw 124h penetrates the second supporting members 124, contacts the gradient magnetic field coil unit 33, and presses the gradient magnetic field coil unit 33 in the Z axis direction.

Although only the magnified chart around the second supporting member 124 in the left side of FIG. 1 is shown in FIG. 11, the other second supporting member 124 in the right side of FIG. 1 and its surrounding parts have the same structure, because the structure of the gradient coil supporting implement 100A is line symmetrical.

Thus, the gradient magnetic field coil unit 33 is pressed from the entrance side toward the deep side of the gantry 30 in the Z axis direction by the two pressing screws 124h of one of the two gradient coil supporting implements 100A.

In addition, the gradient magnetic field coil unit 33 is pressed from the deep side toward the entrance side of the gantry 30 in the Z axis direction by the two pressing screws 124h of the other of the two gradient coil supporting implements 100A.

That is, the gradient magnetic field coil unit 33 is fixed in the Z axis direction by being pressed with two pairs of the twin pressing screws 124 so as to be sandwiched.

In addition, in the first supporting member 122, the part just below the protruded part in an arm shape for fixing the second supporting members 124 and the third supporting members 126 is chamfered so as to be in parallel with the Y-Z plane at installment, and an insertion hole 122f is formed in this surface.

The insertion hole 122f penetrates to the opening AP, and the diameter of the insertion hole 122f is equal to the diameter of the outer ring 110b of the spherical bearing 110. That is, the outer ring 110b of the spherical bearing 110 is included in and interdigitate with the insertion hole 122f at installment.

Because the method of fixing each of the two spherical bearing 110 respectively interdigitated with the two insertion holes 122f of the first supporting member 122 to the plate 31a with the bearing fixing tools FX is the same as the method of fixing the spherical bearing 110 interdigitated with the insertion hole 122h explained with FIG. 9 and FIG. 10, its detailed explanation is omitted.

Note that, in order to achieve the above fixation, four non-illustrated screw holes are formed in the plate 31a (see FIG. 1) at the positions respectively overlapping the totally four screw holes FXb of the two bearing fixing tools FX.

FIG. 12 is a schematic planimetric diagram of the respective first supporting members 122 respectively fixed to end faces of the static magnetic field magnet 31 in the entrance side and the deep side of the gantry 30.

In FIG. 12, the first supporting member 122 is shown by shaded regions, and the plates 31a and 31b are respectively shown by hatching regions.

The first supporting member 122 is separated from the plates 31a and 31b in the Z axis direction, under the state in which the first supporting member 122 is fixed to the plates 31a and 31b in the above manner. This is because the thickness TH1 of the plate part of each bearing fixing tool FX is selected so as to achieve the above condition.

FIG. 13 is a schematic oblique drawing magnifying the part of the second supporting member 124 in FIG. 11.

Although explanation was omitted in FIG. 11 in order to avoid compilation, the part of the second supporting member 124 contacting the third supporting member 126 is formed as a vibration-proof member EL2. This is so that propagation of the vibration from the gradient magnetic field coil unit 33 to the first supporting member 122 via the third supporting member 126 is prevented.

As an example here, the vibration-proof member EL is shown by the hatched region in FIG. 13, and is formed so as to have an L-letter shaped transverse section (the X-Y plane at installment).

The above screw holes 124e is formed in such a manner that its opening side penetrates only through the vibration-proof member EL2 and all portions other than the opening side penetrates only through the metal part of the second supporting members 124.

The screw holes 124a to 124d are formed so as to penetrate only through the metal part of the second supporting members 124.

The vibration-proof member EL2 is formed of elastic material such as rubber or the like. All portions of the second supporting member 124 other than the vibration-proof member EL2 are formed of stainless or the like as described earlier.

FIG. 14 is a schematic oblique drawing showing the state in which the third supporting member 126 is separated from the first supporting member 122 and the second supporting member 124.

FIG. 15 is a schematic oblique drawing showing the state in which the third supporting member 126 has been fixed to the first supporting member 122 and the second supporting member 124 from the state of FIG. 14 and then the RF coil unit 34 is fixed on the third supporting member 126.

In FIG. 14 and FIG. 15, the outline of the third supporting members 126 is indicated by bold lines, the hidden outline of the third supporting members 126 is indicated by dashed lines, and the hidden outlines of the first supporting member 122 and the second supporting members 124 are indicated by chain lines.

In the following, an example of the structure and fixing method of the third supporting members 126 will be explained with reference to FIG. 14 and FIG. 15.

As shown in FIG. 14, the third supporting members 126 is formed in such a manner that its transverse section of the X-Y plane at installment becomes the same anywhere (except the parts around the screw holes 126b, 126e and 126g). The top end (the upper side of the Y axis direction at installment) of the approximately rectangular parallelepiped part of the third supporting members 126 is formed to have a relatively wide width and chamfered in an cylindrical side surface form. This is so that the cylindrically curved surface tightly contacts the outer peripheral surface of the cylindrical RF coil unit 34.

On the top end of the third supporting member 126, a screw hole 126b is formed at the position overlapping the screw hole 34b (see FIG. 15) of the RF coil unit 34 at installment, along the vertical direction (the Y axis direction) at installment.

In addition, the part of the third supporting member 126, which overlaps the surface having the opening of the screw hole 124e of the second supporting members 124, is protruded, and a screw hole 126e is formed on this protruded part.

The screw holes 126e is formed at the position overlapping the screw hole 124e of the second supporting member 124 at installment, along the vertical direction at installment.

In addition, the third supporting member 126 includes a screw hole 126g formed at the lower side in the vertical direction at installment. The screw hole 126g is formed at the position overlapping the screw hole 122g of the first supporting member 122 at installment, along the X axis direction at installment.

Thus, the positioning of the third supporting members 126 to the first supporting member 122 and the second supporting members 124 fixed to each other with the four screws 124g is performed at installment in the following manner. That is, the positioning is performed in such a manner that the positions of the screw hole 126g and the screw hole 122g accord with each other and the positions of the screw hole 126e and the screw holes 124e accord with each other.

In this state, the bottom surface of the protruded part having the screw hole 126e of the third supporting member 126 is brought into close contact with the top surface of the vibration-proof member EL2 of the second supporting members 124, and the respective side surfaces of the first supporting member 122 and the second supporting member 124 including the vibration-proof members EL1 and EL2 are brought into close contact with the side surface of the third supporting member 126.

Under the state in which the positioning has been completed in the above manner, the screw 126f is inserted into the screw hole 126g and the screw hole 122g along the X axis direction to be tightened, and the screw 126d is inserted into the screw hole 126e and the screw hole 124e along the vertical direction to be tightened (see FIG. 15).

In this manner, both third supporting members 126 are fixed to the first supporting member 122 and both second supporting members 124. In this state, because the contact portion between the third supporting member 126 and the second supporting member 124 is only the vibration-proof member EL2, vibration of the gradient magnetic field coil unit 33 hardly propagates to the third supporting member 126 via the second supporting member 124.

As shown in FIG. 15, as an example here, the axis length of the RF coil unit 34 is longer only in the outer peripheral part and this part is formed as the cylindrical protrusion part 34a. The cylindrical protrusion part 34a is protruded from the other parts of the RF coil unit 34 so as to keep an area of inserting the screws 126a in time of fixing the third supporting members 126.

On the protrusion part 34a of the RF coil unit 34, screw holes 34b are formed at the positions respectively overlapping the screw holes 126b of the respective third supporting members 126.

During installation, the RF coil unit 34 is mounted on the top surfaces of the third supporting members 126, after the first supporting member 122, the second supporting members 124 and the third supporting members 126 are mutually united and fixed on the end face of the static magnetic field magnet 31.

At this time, the positioning of the following four parts between the RF coil unit 34 and two gradient coil supporting implements 100A respectively disposed to the entrance side and the deep side of the gantry 30 is performed.

That is, the positioning is performed in such a manner that totally four screw holes 126b of the respective third supporting members 126 of those two gradient coil supporting implements 100A respectively overlap the four screw holes 34b of the RF coil unit 34. Then, the RF coil unit 34 is fixed to the third supporting members 126 by the four screws 126a.

The following is an example of the chronological installment methods of the gradient magnetic field coil unit 33 and the RF coil unit 34 by using the above gradient coil supporting implements 100A.

First, the vibration-proof sheet 32 is placed on the inner cylinder of the static magnetic field magnet 31, and the gradient magnetic field coil unit 33 is mounted on the vibration-proof sheet 32.

Next, the respective first supporting members 122 of those two gradient coil supporting implements 100A are fixed to both end faces of the static magnetic field magnet 31. More specifically, in each of the gradient coil supporting implements 100A, two of the spherical bearings 110 are respectively interdigitated with the two insertion holes 122f (see FIG. 11) and one of the spherical bearings 110 is interdigitated with one insertion hole 122h (see FIG. 7) as described earlier.

In this state, the two spherical bearing 110 are fixed to the plate 31a on the end face with four bearing fixing tools FX as described earlier, and one spherical bearing 110 is fixed to the plate 31b on the end face with two bearing fixing tools FX as described earlier.

Even if the respective surfaces of the plates 31a and 31b are not completely in the same plane at this time, each of the first supporting members 122 can be fixed without generating stress against some distortion because fixation is performed by using the spherical bearings 110.

Next, each pair of the second supporting members 124 is screwed and fixed on each of the two first supporting members 122 respectively fixed to both end faces of the static magnetic field magnet 31, by using four screws 124g for each second supporting member 124 as described earlier.

After this, totally four pressing screws 124h are inserted into both pairs of the screw holes 124f (see FIG. 15) and tightened so as to sandwich the gradient magnetic field coil unit 33 in the Z axis direction

Next, both pair of the third supporting members 126 are respectively fixed to both of the united pairs of the first and second supporting members 122 and 124 respectively fixed on both end faces of the static magnetic field magnet 31, as described earlier.

Next, the RF coil unit 34 is mounted on totally four third supporting members 126, in such a manner that the protrusion part 34a is placed on the top surfaces the third supporting members 126.

After this, the RF coil unit 34 is fixed to the third supporting members 126, in a state where the RF coil unit 34 is floating from the gradient magnetic field coil unit 33 as described earlier.

The foregoing is an example of installing methods.

FIG. 16 is a block diagram showing general structure of the MRI apparatus 10A according to the first embodiment. As an example here, the components of the MRI apparatus 10A will be explained by classifying them into three groups which are a bed unit 20, a gantry 30 and a control device 40.

Firstly, the bed unit 20 includes a bed 21, a table 22, and a table moving structure 23 disposed inside the bed 21. An object P is loaded on the top surface of the table 22. In addition, inside the table 22, a reception RF coil 24 for detecting MR signals from the object P is disposed. Moreover, a plurality of connection ports 25 to which wearable type RF coil devices are connected are disposed on the top surface of the table 22.

The bed 21 supports the table 22 in such a manner that the table 22 can move in the horizontal direction (i.e. the Z axis direction).

The table moving structure 23 adjusts the position of the table 22 in the vertical direction by adjusting the height of the bed 21, when the table 22 is located outside the gantry 30.

In addition, the table moving structure 23 inserts the table 22 into inside of the gantry 30 by moving the table 22 in the horizontal direction and moves the table 22 to outside of the gantry 30 after completion of imaging.

Secondly, the gantry 30 is shaped in the form of a cylinder, for example, and is installed in an imaging room. The gantry 30 includes the static magnetic field magnet 31, the gradient magnetic field coil unit 33, the RF coil unit 34 and two gradient coil supporting implements 100A, as mentioned earlier.

The static magnetic field magnet 31 is, for example, a superconductivity coil and forms a static magnetic field in an imaging space by using electric currents supplied from the later-described static magnetic field power supply 42. The aforementioned imaging space means, for example, a space in the gantry 30 in which the object P is placed and to which the static magnetic field is applied. Note that the static magnetic field magnet 31 may include a permanent magnet which makes the static magnetic field power supply 42 unnecessary.

The gradient magnetic field coil unit 33 includes an X axis gradient magnetic field coil 33x, a Y axis gradient magnetic field coil 33y and a Z axis gradient magnetic field coil 33z.

The X axis gradient magnetic field coil 33x forms a gradient magnetic field Gx in the X axis direction in an imaging region in accordance with an electric current supplied from the later-described X axis gradient magnetic field power supply 46x.

Similarly, the Y axis gradient magnetic field coil 33y forms a gradient magnetic field Gy in the Y axis direction in the imaging region in accordance with an electric current supplied from the later-described Y axis gradient magnetic field power supply 46y.

Similarly, the Z axis gradient magnetic field coil 33z forms a gradient magnetic field Gz in the Z axis direction in the imaging region in accordance with an electric current supplied from the later-described Z axis gradient magnetic field power supply 46z.

Thereby, directions of a gradient magnetic field Gss in a slice selection direction, a gradient magnetic field Gpe in a phase encoding direction and a gradient magnetic field Gro in a readout (frequency encoding) direction can be arbitrarily selected as logical axes, by combining the gradient magnetic fields Gx, Gy and Gz in the X axis, the Y axis and the Z axis directions as three physical axes of the apparatus coordinate system.

The above imaging region means, for example, at least a part of an acquisition range of MR signals used to generate one image or one set of images, which becomes an image. The imaging region is three-dimensionally defined as a part of the imaging space in terms of range and position by the apparatus coordinate system, for example.

For example, when MR signals are acquired in a range wider than a region made into an image in order to prevent aliasing (artifact), the imaging region is a part of the acquisition range of MR signals.

On the other hand, in some cases, the entire acquisition range of MR signals becomes an image, i.e. the imaging region and the acquisition range of MR signals agree with each other. In addition, the above one set of images means, for example, a plurality of images when MR signals of the plurality of images are acquired in a lump in one pulse sequence such as multi-slice imaging.

The RF coil unit 34 includes a whole body coil that combines a function of transmitting RF pulses and a function of detecting MR signals, as an example here. The RF coil unit 34 may further include a transmission RF coil that exclusively performs transmission of RF pulses.

Thirdly, the control device 40 includes the static magnetic field power supply 42, a gradient magnetic field power supply 46, an RF transmitter 48, an RF receiver 50, a sequence controller 58, an operation device 60, an input device 72, a display device 74 and the storage device 76.

The gradient magnetic field power supply 46 includes the X axis gradient magnetic field power supply 46x, the Y axis gradient magnetic field power supply 46y and the Z axis gradient magnetic field power supply 46z.

The X axis gradient magnetic field power supply 46x, the Y axis gradient magnetic field power supply 46y and the Z axis gradient magnetic field power supply 46z supply the respective electric currents for forming the gradient magnetic field Gx, the gradient magnetic field Gy and the gradient magnetic field Gz to the X axis gradient magnetic field coil 33x, the Y axis gradient magnetic field coil 33y and the Z axis gradient magnetic field coil 33z, respectively.

The RF transmitter 48 generates RF pulse electric currents of the Larmor frequency for causing nuclear magnetic resonance in accordance with control information inputted from the sequence controller 58, and transmits the generated RF pulse electric currents to the RF coil unit 34. The RF pulses in accordance with these RF pulse electric currents are transmitted from the RF coil unit 34 to the object P.

The whole body coil of the RF coil unit 34 and the reception RF coil 24 detect MR signals generated due to excited nuclear spin inside the object P by the RF pulses and the detected MR signals are inputted to the RF receiver 50.

The RF receiver 50 generates raw data which are digitized complex number data of MR signals obtained by performing predetermined signal processing on the received MR signals and then performing A/D (analogue to digital) conversion on them.

The RF receiver 50 inputs the generated raw data of MR signals to the later-described image reconstruction unit 62 of the operation device 60.

The sequence controller 58 stores control information needed in order to make the gradient magnetic field power supply 46, the RF transmitter 48 and the RF receiver 50 drive in accordance with commands from the operation device 60. The aforementioned control information includes, for example, sequence information describing operation control information such as intensity, application period and application timing of the pulse electric currents which should be applied to the gradient magnetic field power supply 46.

The sequence controller 58 generates the gradient magnetic fields Gx, Gy and Gz and RF pulses by driving the gradient magnetic field power supply 46, the RF transmitter 48 and the RF receiver 50 in accordance with a predetermined sequence stored.

The operation device 60 includes a system control unit 61, a system bus SB, an image reconstruction unit 62, a image database 63 and an image processing unit 64.

The system control unit 61 performs system control of the MRI apparatus 10A in setting of imaging conditions of a main scan, an imaging operation and image display after imaging through interconnection such as the system bus SB.

The aforementioned term “imaging condition” refers to under what condition RF pulses or the like are transmitted in what type of pulse sequence, or under what condition MR signals are acquired from the object P, for example.

As parameters of the imaging conditions, for example, there are an imaging region as positional information in the imaging space, the number of slices, an imaging part and the type of the pulse sequence such as spin echo and parallel imaging. The above imaging part means a region of the object P to be imaged, such as a head and a chest.

The aforementioned main scan is a scan for imaging an intended diagnosis image such as a T1 weighted image, and it does not include a scan for acquiring MR signals for a scout image or a calibration scan. A scan is an operation of acquiring MR signals, and it does not include image reconstruction processing.

The calibration scan is a scan for determining unconfirmed elements of imaging conditions, conditions and data used for image reconstruction processing and correction processing after the image reconstruction, and the calibration is performed separately from the main scan.

A sequence of calculating the center frequency of the RF pulses in the main scan is an example of the calibration scan. A prescan is one of the calibration scan, which is performed before the main scan.

In addition, the system control unit 61 makes the display device 74 display screen information for setting imaging conditions, sets the imaging conditions on the basis of command information from the input device 72, and inputs the determined imaging conditions to the sequence controller 58. In addition, the system control unit 61 makes the display device 74 display images indicated by the generated display image data after completion of imaging.

The input device 72 provides a user with a function to set the imaging conditions and image processing conditions.

The image reconstruction unit 62 arranges and stores the raw data of MR signals inputted from the RF receiver 50 as k-space data, in accordance with the phase encode step number and the frequency encode step number. The above k-space means a frequency space. The image reconstruction unit 62 generates image data of the object P by performing image reconstruction processing including such as two-dimensional or three-dimensional Fourier transformation and so on. The image reconstruction unit 62 stores the generated image data in the image database 63.

The image processing unit 64 takes in the image data from the image database 63, performs predetermined image processing on them, and stores the image data after the image processing in the storage device 66 as display image data.

The storage device 76 stores the display image data after adding accompanying information such as the imaging conditions used for generating the display image data and information of the object P (patient information) to the display image data.

Note that, the four units as an operation device 60, an input device 72, a display device 74 and the storage device 76 may be constituted as one computer to be disposed in a control room, for example.

In addition, though the components of the MRI apparatus 10A are classified into three groups (the gantry 30, the bed unit 20 and the control device 40) in the above explanation, this is only an example of interpretation.

For example, the table moving structure 23 may be interpreted as a part of the control device 40.

Alternatively, the RF receiver 50 may be included not outside the gantry 30 but inside the gantry 30. In this case, for example, an electronic circuit board that is equivalent to the RF receiver 50 may be disposed in the gantry 30. Then, the MR signals, which are analog electrical signals converted from the electromagnetic waves by the reception RF coil 24 and so on, may be amplified by a pre-amplifier in the electronic circuit board, then the amplified signals may be outputted to the outside of the gantry 30 as digital signals and inputted to the image reconstruction unit 62. In outputting the signals to the outside of the gantry 30, for example, an optical communication cable is preferably used to transmit the signals in the form of optical digital signals. This is because the effect of external noise is reduced.

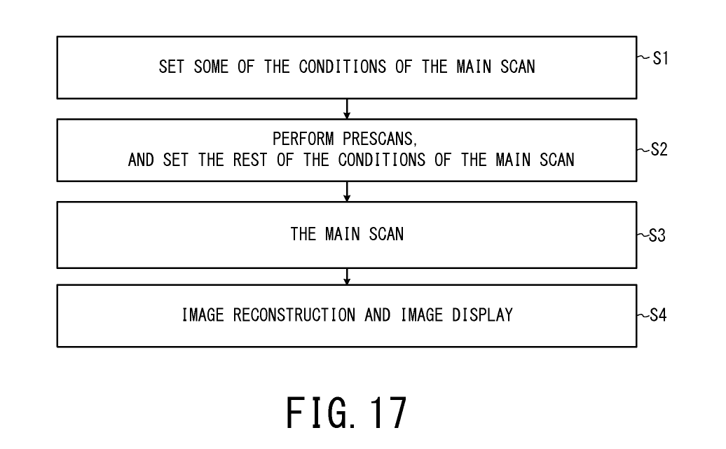

FIG. 17 is a flowchart illustrating an example of a flow of a process performed by the MRI apparatus 10A of the first embodiment. In the following, according to the step numbers in the flowchart shown in FIG. 17, an example of the operations of the MRI apparatus 10A will be described.

[step S1] The system control unit 61 sets some of the imaging conditions of the main scan on the basis of the imaging conditions inputted to the MRI apparatus 10A via the input device 72.

After this, the process proceeds to Step S2.

[Step S2] The system control unit 61 controls each unit of the MRI apparatus 10A so as to perform prescans, and sets the undefined imaging conditions of the main scan such as the center frequency of RF pulses on the basis of the execution results of the prescans.

Note that, the gradient magnetic field coil unit 33 vibrates during implementation term of the prescans, because the electric currents for generating the gradient magnetic fields Gx, Gy and Gz respectively flow in the X axis gradient magnetic field coil 33x, the Y axis gradient magnetic field coil 33y and the Z axis gradient magnetic field coil 33z.

However, propagation of the vibration of the gradient magnetic field coil unit 33 to the side of static magnetic field magnet 31 is prevented, because the gradient magnetic field coil unit 33 is supported so as to be sandwiched in the Z axis direction by the above gradient coil supporting implements 100A.

After this, the process proceeds to Step S3.

[step S3] The system control unit 61 controls each component of the MRI apparatus 10A so as to perform the main scan.

More specifically, a static magnetic field has been formed in the imaging space by the static magnetic field magnet 31 excited by the static magnetic field power supply 42 after Step S2.

Then, when the system control unit 61 receives a start command of imaging from the input device 72, the system control unit 61 inputs imaging conditions including a pulse sequence into the sequence controller 58.

Then, the sequence controller 58 drives the gradient magnetic field power supply 46, the RF transmitter 48 and the RF receiver 50 in accordance with the inputted pulse sequence, thereby gradient magnetic fields are formed in the imaging region including the imaging part of the object P, and RF pulses are generated from the RF coil unit 34.

Then, MR signals generated by nuclear magnetic resonance inside the object P are detected by the RF coil device 80, the reception RF coil 24 and so on, and the detected MR signals are inputted to the RF receiver 50.

The RF receiver 50 performs the aforementioned predetermined signal processing on the inputted MR signals so as to generate the raw data of MR signals, and inputs these raw data into the image reconstruction unit 62.

The image reconstruction unit 62 arranges and stores the raw data of MR signals as k-space data.

Note that, though the gradient magnetic field coil unit 33 vibrates during implementation term of the above main scan in the way similar to the implementation term of the prescans, propagation of the vibration of the gradient magnetic field coil unit 33 to the static magnetic field magnet 31 side is prevented by the gradient coil supporting implements 100A.

After this, the process proceeds to Step S4.

[Step S4] The image reconstruction unit 62 reconstructs image data by performing image reconstruction processing including Fourier transformation on the k-space data, and stores the reconstructed image data in the image database 63.

The image processing unit 64 obtains the image data from the image database 63 and generates two-dimensional display image data by performing predetermined image processing on the obtained image data. The image processing unit 64 stores the display image data in the storage device 76.

After this, the system control unit 61 makes the display device 74 display images indicated by the display image data.

The foregoing is a description of an operation of the MRI apparatus 10A according to the present embodiment.

In the following, the difference between conventional technology and the first embodiment will be explained.

Consider a case where the spherical bearing 110 is not used. In this case, it is difficult to mount the first supporting member 122 to the plates 31a and 31b in parallel with each other so as to be highly balanced between the left and right sides, unless (a) precision of flatness of the first supporting members 122, (b) precision of dimension of each component of the first supporting members 122, (c) flatness of the end plates of the vacuum container of the static magnetic field magnet 31 and (d) flatness of the plates 31a and 31b are all extremely satisfactory.

If the first supporting member 122 is not fixed to the plates 31a and 31b in parallel with each other so as to be highly balanced between the left and right sides, moment of force is applied to components connecting the first supporting members 122 with the plates 31a and 31b.

Then, in the first embodiment, the spherical bearings 110 are used in order to cancel the moment of force. The respective shafts 110a of the three spherical bearings 110 respectively interdigitated with three holes 122f, 122h of the first supporting member 122 can tilt in accordance with a slight inclination between the respective surfaces of the first supporting member 122 and the plates 31a and 31b, in time of fixing the first supporting member 122.

This is because the spherical inner surface of the outer ring 110b and the spherical lateral surface of the flange FR slide. Thereby, stress against the first supporting member 122 hardly occurs after fixing the first supporting member 122.

In addition, the thickness TH1 of each of the bearing fixing tools FX is selected in such a manner that the first supporting member 122 is separated from the plates 31a and 31b by the interval DD. Because moment of force is suppressed by separating the first supporting member 122 as the main body of the gradient coil supporting implement 100A from the end plate of the static magnetic field magnet 31, the vacuum container of the static magnetic field magnet 31 is protected more effectively than the structure of conventional technology.

Moreover, the first supporting member 122 is fixed to the end face of the static magnetic field magnet 31 at three positions. Although it is difficult to position four fixation points in the same plane in the case of four-point fixation, three fixation points are inevitably positioned in the same plane in the case of three-point fixation. Thus, the first supporting member 122 can be stably fixed to the plates 31a and 31b.

In other words, local stress is relaxed by using the spherical bearings 110 at the connection parts in the first embodiment, in addition to suppressing moment of force by separating the gradient coil supporting implement 100A from the end plate side (the plates 31a and 31b side) of the static magnetic field magnet 31 by the interval DD.

Thereby, it can prevent vibration due to rocking during transport and vibration of the gradient magnetic field coil unit 33 during imaging operation from propagating to each component of the gantry 30. As a result, the MRI apparatus 10A being quieter in noise than conventional technology can be provided.

According to the aforementioned embodiment, a novel MRI technology to prevent vibration of the gradient magnetic field coil unit 33 from propagating to the side of the static magnetic field magnet 31 can be provided.

### The Second Embodiment

The MRI apparatus of the second embodiment includes two gradient coil supporting implements 100B instead of the two gradient coil supporting implements 100A in the first embodiment. Each of the gradient coil supporting implements 100B has the same structure as the gradient coil supporting implement 100A in the first embodiment, except that vibration-proof structure is further provided in the connection parts between the RF coil unit 34 and the third supporting members 126′.

Although the symbol of the MRI apparatus of the second embodiment is defriend as 10B for the sake of convenience, the difference is only the above point. Thus, the overall chart of the MRI apparatus 10B is omitted and only the difference between the first and second embodiments will be explained.

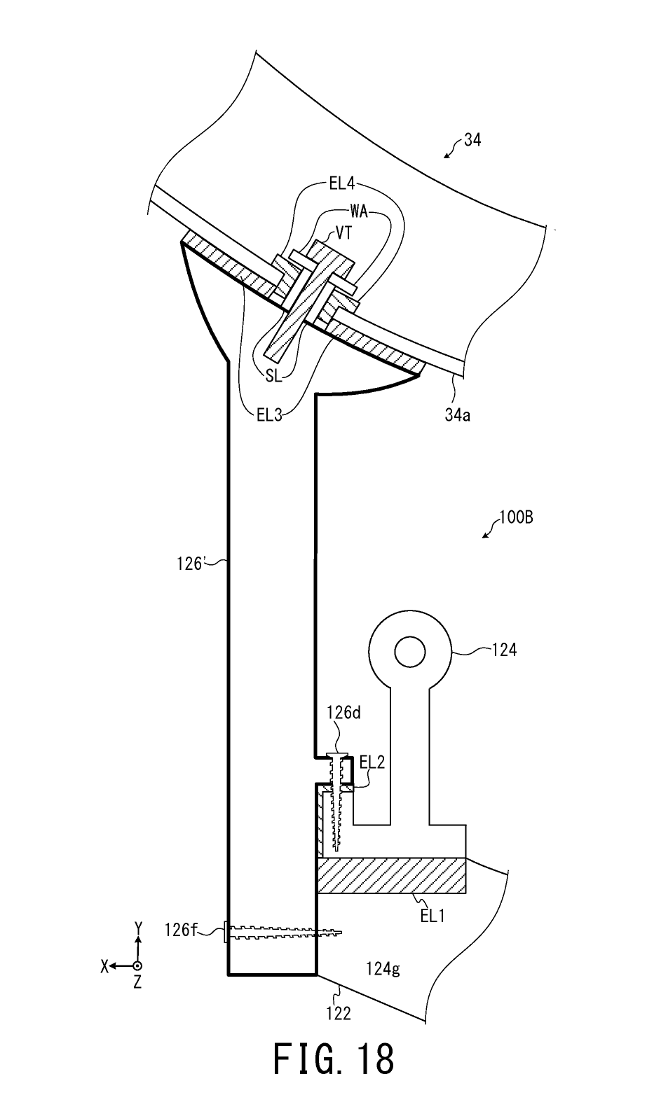

FIG. 18 is a schematic cross-sectional diagram showing an example of the structure of the third supporting member 126′ of the gradient coil supporting implement 100B in the second embodiment.

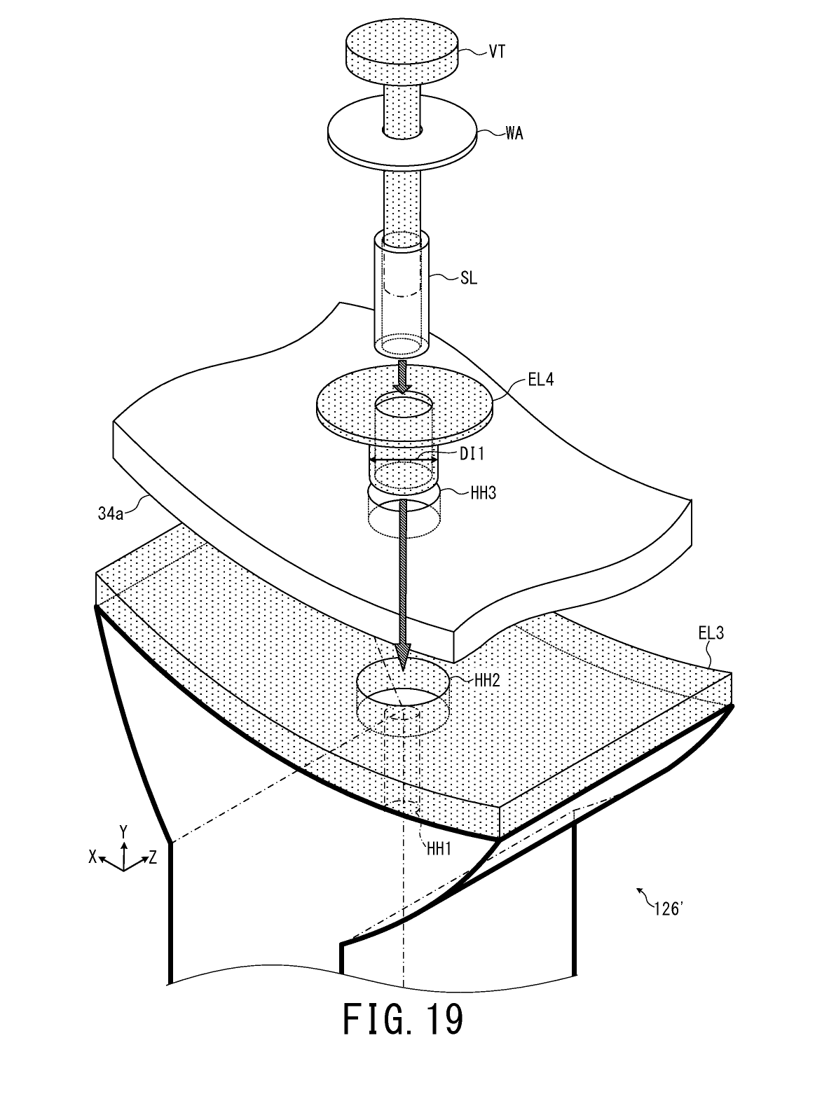

FIG. 19 is a schematic exploded perspective view of the connecting part between the third supporting member 126′ and the RF coil unit 34 in FIG. 18. In FIG. 18 and FIG. 19, the outline of the metal part lower than the vibration-proof member EL3 of the third supporting member 126′ is indicated by bold lines, and hidden outline of this metal part is indicated by chain lines.

In the following, coupling structure between the RF coil unit 34 and the third supporting members 126′ will be explained with reference to FIG. 18 and FIG. 19.

As shown in FIG. 18, the gradient coil supporting implement 100B includes a bolt VT, a washer WA, a sleeve SL and the vibration-proof members EL3 and EL4 for fixing the RF coil unit 34. In addition, the outline of the third supporting member 126′ of the gradient coil supporting implement 100B is similar to that of the first embodiment, and the third supporting member 126′ is coupled to the first supporting member 122 and the second supporting members 124 in the way similar to the first embodiment.

As shown in FIG. 19, a cylindrical fixing hole HH1, whose opening diameter is approximately the same as the tip side of the bolt VT, is formed on the top surface of the third supporting member 126′.

The vibration-proof members EL3 and EL4 are formed of rubber or the like, and insulates propagation of vibration between the RF coil unit 34 and the third supporting member 126′.

The vibration-proof member EL3 is, for example, sheet shaped and is connected to the top surface of the third supporting member 126′. A cylindrical fixing hole HH2 is formed in the vibration-proof member EL3 at the position overlapping the fixing hole HH1.

The vibration-proof member EL4 has a shape obtained by connecting a ring part with a cylinder part which is smaller than this ring part in outer diameter but equal to this ring part in inner diameter.

The diameter of the fixing hole HH2 of the vibration-proof member EL3 is equal to the outer diameter DI1 of the cylinder part of the vibration-proof member EL4 or slightly larger than this outer diameter DI1. Because the vibration-proof member EL3 is connected to the top surface of the third supporting member 126′ as an example here, the vibration-proof member EL3 is interpreted as a part of the third supporting member 126′.

In the protrusion part 34a of the RF coil unit 34, a cylindrical fixing hole HH3 is formed at the position overlapping the fixing hole HH2 (actually, the number of the fixing holes HH1, HH2 and HH3 is respectively four because four third supporting member 126′ are included in two gradient coil supporting implement 100B). The diameter of the fixing hole HH3 of the protrusion part 34a is equal to the outer diameter DI1 of the cylinder part of the vibration-proof member EL4.

In the above structure, an example of methods of installing the gradient magnetic field coil unit 33 and the RF coil unit 34 is as follows.

First, each of the first supporting members 122 is fixed to the plates 31a and 31b, then each pair of the second supporting members 124 are fixed onto each of the first supporting members 122, then the gradient magnetic field coil unit 33 is supported by the pressing screws 124h, and then each pair of the third supporting members 126′ are fixed to the united first and second supporting members 122, 124. So far, it is the same as the first embodiment.

Next, the RF coil unit 34 is mounted on totally four third supporting members 126′ in such a manner that the protrusion part 34a is placed on the vibration-proof members EL3. At this time, positioning is performed in such a manner that the respective fixing holes HH1, HH2 and HH3 are coaxially positioned.

Under the state where the above positioning has been completed, each of the vibration-proof members EL4 is inserted through the respective fixing holes HH1, HH2 and HH3.

Next, each of the sleeves SL is inserted into the opening of each of the vibration-proof members EL4. Here, the sleeve SL is in the form of a cylinder and its inner diameter is larger than the diameter of the fixing hole HH1 of the third supporting members 126′. Thus, though each of the sleeves SL passes through the fixing holes HH2 and HH3, each of the sleeves SL is not inserted deeper than the metal part of the third supporting members 126′.

Next, under the state where each washer WA is placed on each sleeve SL, each bolt VT is inserted into the deepest part of the fixing hole HH1 so as to penetrate the washer WA and the sleeve SL.

Thereby, the RF coil unit 34 is fixed onto the third supporting members 126′.

As just described, the same effects as the first embodiment can be obtained in the second embodiment.

Moreover, because vibration insulating structure including the vibration-proof members EL3 and EL4 is provided on the edge of each of the third supporting members 126′, propagation of the vibration of the gradient magnetic field coil unit 33 to the RF coil unit 34 side is more surely prevented in the second embodiment.

### The Third Embodiment

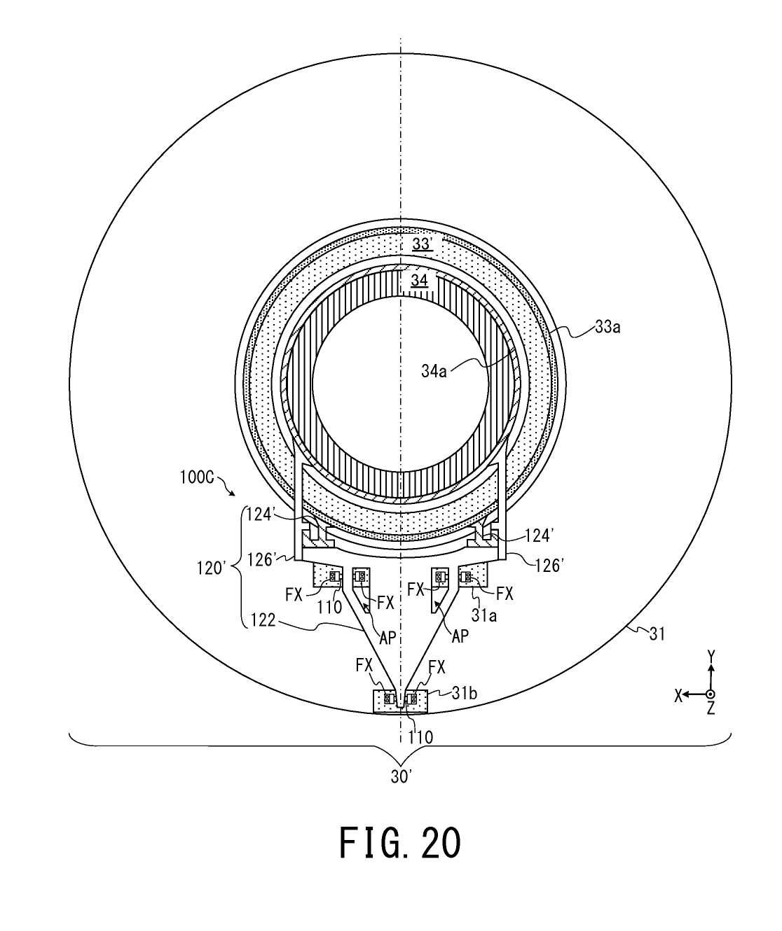

FIG. 20 is a schematic planimetric diagram of the gantry 30′ of the MRI apparatus of the third embodiment. The gantry 30′ of the MRI apparatus of the third embodiment includes two gradient coil supporting implement 100C instead of the two gradient coil supporting implement 100B of the second embodiment.

The third embodiment is the same as the second embodiment, except that the gradient magnetic field coil unit 33′ is supported by the second supporting members 124′ of the gradient coil supporting implements 100C in a state floating from the static magnetic field magnet 31. Thus, the vibration-proof sheet 32 in the first embodiment and the second embodiment is omitted in the third embodiment.

Note that, though the symbol of the MRI apparatus of the third embodiment is defined as 10C for the sake of convenience, the overall chart of the MRI apparatus 10C is omitted because the difference is only the above point.

In order to achieve fixation in a floating state, the outer periphery part of the container of the gradient magnetic field coil unit 33′ of the MRI apparatus 10C in the third embodiment is protruded in the way similar to the RF coil unit 34. That is, the gradient magnetic field coil unit 33′ is shown by the combined region of the annular area of dense hatching and the annular area of thinner hatching in FIG. 20, and the outer periphery side of its container is formed as a protruded part 33a whose axial length is larger than the rest of the gradient magnetic field coil unit 33′.

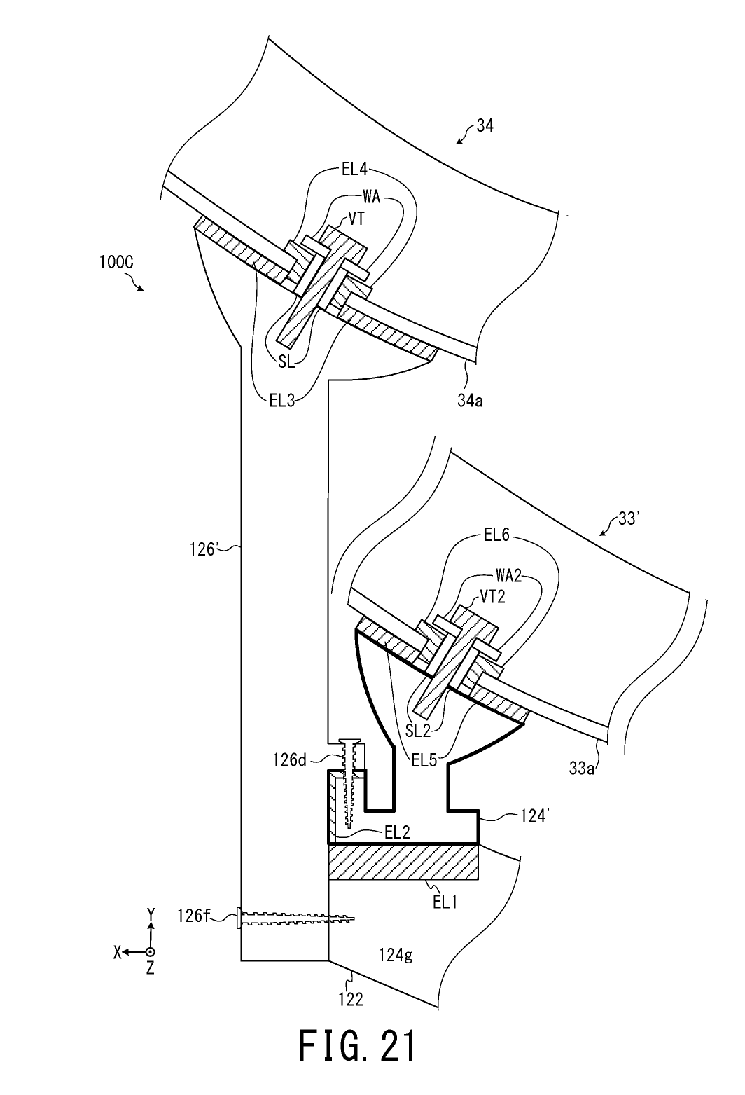

As explained in the next FIG. 21, the gradient magnetic field coil unit 33′ is fixed to the second supporting members 124′ of the gradient coil supporting implements 100C with bolts via fixation holes formed on this protruded part 33a.

FIG. 21 is a schematic cross-sectional diagram showing an example of the second supporting member 124′ of the gradient coil supporting implement 100C in the third embodiment. In FIG. 21, the outline of the metal part of the second supporting members 124′ lower than the vibration-proof member EL5 in the vertical direction is indicated by bold lines.

As shown in FIG. 21, the coupling structure between the gradient magnetic field coil unit 33′ and the second supporting members 124′ is similar to the coupling structure between the RF coil unit 34 and the third supporting members 126′ in the second embodiment. More specifically, the gradient coil supporting implement 100C includes bolts VT2, washers WA2, sleeves SL2 and vibration-proof members EL5 and EL6 for supporting and fixing the gradient magnetic field coil unit 33′.

In addition, the outline of the second supporting member 124′ is the same as the first embodiment except its tip part (the side of the gradient magnetic field coil unit 33′ at installment), and the second supporting members 124′ are fixed to the first supporting member 122 in the way similar to the first embodiment. The tip part of the second supporting member 124′ has the vibration-proof structure similar to the tip part of the third supporting member 126′. The tip part of the second supporting member 124′ is chamfered in a shape closely adhering to the cylindrical outer periphery surface of the protruded part 33a of the gradient magnetic field coil unit 33′.

In addition, a non-illustrated cylindrical fixation hole, whose opening diameter is approximately the same as the tip side of the bolt VT2, is formed on the top surface of each of the second supporting members 124′.

The vibration-proof members EL5 and EL6 are formed of rubber or the like, and insulates propagation of the vibration between the gradient magnetic field coil unit 33′ and the second supporting members 124′. Each of the vibration-proof members EL5 is, for example, sheet shaped, and connected to the top surface of the second supporting member 124′.

A non-illustrated cylindrical fixation hole is formed in each of the vibration-proof member EL5 at the position overlapping the fixation hole in the top surface of the second supporting member 124′. The vibration-proof member EL6 has the same structure as the vibration-proof member EL4 in the second embodiment.

In addition, non-illustrated cylindrical fixation holes are formed in the protrusion part 34a of the gradient magnetic field coil unit 33′ at the positions respectively overlapping the fixation holes of the vibration-proof members EL5.

In the above structure, an example of methods of installing the gradient magnetic field coil unit 33 and the RF coil unit 34 is as follows.

First, each of the first supporting members 122 is fixed to the plates 31a and 31b, and each pair of the second supporting members 124 is fixed to each of the first supporting members 122.

Next, the gradient magnetic field coil unit 33′ are mounted on totally four second supporting members 124′ in such a manner that the protruded part 33a is placed on the vibration-proof members EL5. At this time, positioning is performed in such a manner that the fixation holes of the protruded part 33a are positioned respectively coaxial to the fixation holes in the top surface of the second supporting members 124′.

Under the state in which the above positioning has been completed, the vibration-proof members EL6 are respectively inserted through these fixation holes.

Next, each sleeve SL2 is inserted into the opening of each of the vibration-proof members EL6.

Next, under the state in which each washer WA2 is mounted on each sleeve SL2, each bolt VT2 is inserted into the deepest part of the fixation hole of the second supporting members 124′ so as to pass through the washer WA2 and the sleeve SL2. Thereby, the gradient magnetic field coil unit 33′ is fixed to the second supporting members 124′.

After this, the RF coil unit 34 is fixed after two pairs of the third supporting members 126′ are respectively fixed to the united first and second supporting members 122 and 124′, in the way similar to the second embodiment.

As just described, the same effects as the second embodiment can be obtained in the third embodiment.

Moreover, in the third embodiment, the gradient magnetic field coil unit 33′ can be fixed in a state floating from the static magnetic field magnet 31.

In addition, because the vibration-proof structure including the vibration-proof members EL5 and EL6 is provided in the tip of each of the second supporting members 124′ that directly support the gradient magnetic field coil unit 33′, propagation of the vibration of the gradient magnetic field coil unit 33 to the RF coil unit 34 side is more securely prevented.

(Supplementary Notes on Embodiments)

[1] As to the gradient coil supporting implement 100C of the third embodiment, an example in which the joining part of the first supporting member 122 with the second supporting members 124′ is formed as the vibration-proof member EL1 has been explained. However, embodiments of the present invention are not limited to such an aspect.

When insulation of the vibration from the gradient magnetic field coil unit 33′ is achieved by including the vibration-proof members EL5 and EL6 on the tip of the second supporting members 124′ like the third embodiment, it is not necessary to doubly insulate the vibration. Thus, as an modified version of the third embodiment, a gradient coil supporting implement 100D may omit the vibration-proof member EL1 and have the first supporting member which is entirely formed of metal such as stainless or FRP.

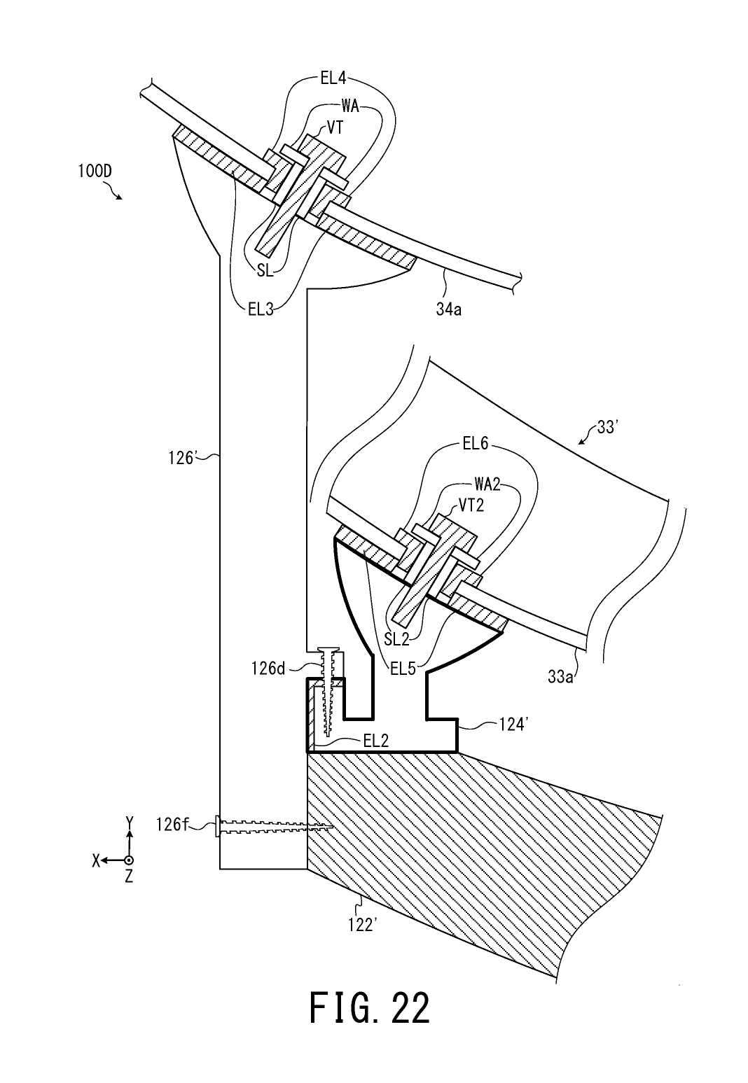

FIG. 22 is a schematic cross-sectional diagram showing an example of the structure of the gradient coil supporting implement 100D of the modified version of the third embodiment.

In FIG. 22, the first supporting member 122′ is the right-downward slant line region. In the case of the MRI apparatus whose vibration of the gradient magnetic field coil unit 33′ is designed to be small, the vibration-proof member EL1 may be omitted in the same way as mentioned above.

[2] In the third embodiment, an example in which the washers WA, the sleeves SL, the vibration-proof members EL3 and EL4 or the like are disposed on the tip of the third supporting members 126′ in order to prevent propagation of the vibration to the RF coil unit 34 has been explained. However, embodiments of the present invention are not limited to such an aspect.

Structure of insulating vibration to the RF coil unit 34 is nonessential. For example, in the gradient coil supporting implement 100C of the third embodiment, the third supporting members 126 of the first embodiment may be used instead of the third supporting members 126′.

[3] The aforementioned structures of the respective components of the gradient coil supporting implements 100A to 100D are only examples, and the structures of the respective components can be appropriately changed in accordance with the structure of each component of the gantry 30.

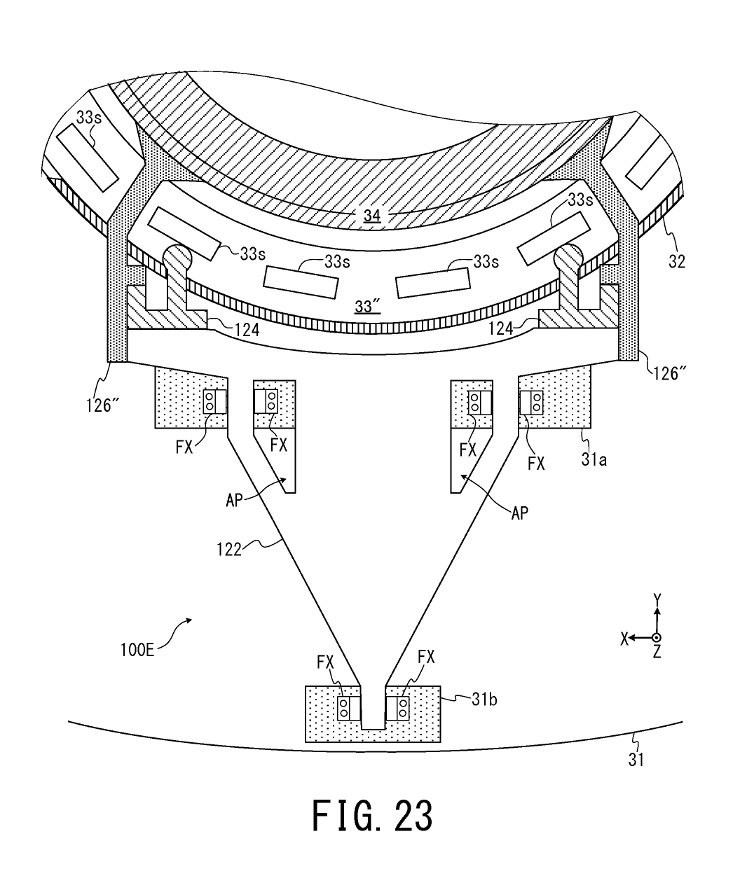

FIG. 23 is a schematic planimetric diagram showing an example of the structure of the gradient coil supporting implement 100E of the modified version of the first embodiment.

In this example, a plurality of insertion holes 33s for inserting shim trays are protruded in the gradient magnetic field coil unit 33″. In this case, each of the third supporting members 126″ has a bent shape so as to avoid these insertion holes 33s. The gradient coil supporting implement 100E has the same structure as the gradient coil supporting implement 100A of the first embodiment, except that the third supporting members 126″ are bent.

[4] Examples in which main components of the gantry 30 such as the static magnetic field magnet 31, the gradient magnetic field coil unit 33 and the RF coil unit 34 are in the form of cylinder have been explained. However, embodiments of the present invention are not limited to such an aspect.

For example, the cross-section of the bore functioning as the imaging space and the cross-section of the entire gantry may be square. That is, as long as the gantry has a structure of disposing the gradient magnetic field coil unit inside the static magnetic field magnet, the gradient coil supporting implements 100A to 100E of the above embodiments are applicable by changing the shape of each component appropriately.

[5] Examples in which the static magnetic field magnet 31 is composed as a superconductive magnet and included in the vacuum container have been explained. However, embodiments of the present invention are not limited to such an aspect.

The aforementioned gradient coil supporting implements 100A to 100E can be applied to cases where a static magnetic field magnet has a structure of including a permanent magnet in a container.

[6] In the above embodiments, examples in which the first supporting member 122 is fixed to the end face of the static magnetic field magnet 31 via the spherical bearings 110 respectively positioned at three points in a state floating from the static magnetic field magnet 31 have been explained. However, embodiments of the present invention are not limited to such an aspect.

Consider a case in where (a) each surface of the plates 31a and 31b is completely flat, (b) the surface of the first supporting member 122 on the static magnetic field magnet 31 side is completely flat and (c) those component are formed with dimension accurate enough to keep each surface of the plates 31a and 31b perfectly in parallel with the first supporting member 122. In such an ideal case, the first supporting member may be fixed onto the plates 31a and 31b via three cylindrical rods (pins) instead of the three spherical bearings 110.

In this case, the cylindrical rod and the insertion holes 122f and 122h are formed so as to have the same diameter as the cylindrical rod CY of the shaft 110a of the spherical bearing 110, and the first supporting member may be fixed onto the plates 31a and 31b by using the bearing fixing tools FX.

Alternatively, in the gradient coil supporting implement 100A of the first embodiment, only the spherical bearing 110 interdigitated with the insertion hole 122h of the first supporting member 122 in FIG. 10 may be substituted for another bearing such as a sliding bearing. In this case, because the spherical bearings 110 are used for the other two parts for bearing, line symmetry of the gradient coil supporting implement 100A is kept.

Alternatively, in the gradient coil supporting implement 100A of the first embodiment, the two spherical bearings 110 respectively interdigitated with the insertion hole 122f in FIG. 11 and the insertion hole 122f on the opposite side (non-illustrated because it has a line symmetrical outline) may be substituted for other two bearings such as sliding bearings. In this case, out of all the bearings of the gradient coil supporting implement, only the bearing interdigitated with the insertion hole 122h of the first supporting member 122 in FIG. 10 is the spherical bearing 110 and its line symmetry is kept.

That is, in the case of three-point fixation, it is the most desirable to respectively use three spherical bearings in the three fixation points. However, by using a spherical bearing at least in one fixation point, the aforementioned effects can be obtained to some extent. This point holds true for the gradient coil supporting implements 100B to 100E of the other embodiments. In addition, in the case of using other bearings such as a sliding bearing, it is preferable to apply resin coating on the surface of the flange and inside surface of the outer ring in order to reduce noise, as described earlier.

[7] Although the gradient coil supporting implement (100A to 100E) is used for the name of the invention in the above explanation, this is only an example of the title. The gradient coil supporting implements 100A to 100E may be interpreted as an auxiliary instrument for setting a gradient coil or a gradient coil attachment tools.

[8] While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A gradient coil supporting implement supporting a gradient magnetic field coil unit installed at an inner side of a static magnetic field magnet in an magnetic resonance apparatus, the gradient coil supporting implement comprising:
three bearings whose shafts are respectively fixed to an end face of the static magnetic field magnet; and
a mounting main body configured to be fixed to the end face of the static magnetic field magnet via the three bearings, and support the gradient magnetic field coil unit at least in a horizontal direction by being partially made in contact with the gradient magnetic field coil unit,
wherein one end side of the mounting main body is configured to be fixed to an outer periphery side of the end face of the static magnetic field magnet, at one position via one of the three bearings;
another end side of the mounting main body is configured to be fixed to an inner periphery side of the end face of the static magnetic field magnet, at two positions via two of the three bearings; and
at least one of the three bearings is a spherical bearing.

2. The gradient coil supporting implement according to claim 1,
wherein at least two of the three bearings are spherical bearings;
the mounting main body includes a first supporting member fixed to the end face of the static magnetic field magnet via the three bearings and a second supporting member fixed to the first supporting member;
the first supporting member is configured to be fixed to the outer periphery side of the end face of the static magnetic field magnet via one of the three bearings on one end side, and to be fixed to the inner periphery side of the end face of the static magnetic field magnet at two positions via two spherical bearings on another end side; and
the second supporting member is configured to be fixed to fixed to said another end side of the first supporting member, and to support the gradient magnetic field coil unit at least in the horizontal direction by being partially made in contact with the gradient magnetic field coil unit.

3. The gradient coil supporting implement according to claim 2,
wherein the mounting main body further includes a vibration-proof member fixed to said another end side of the first supporting member; and
the second supporting member is fixed to said another end side of the first supporting member via the vibration-proof member.

4. The gradient coil supporting implement according to claim 3,
wherein the mounting main body further includes a third supporting member configured to be fixed to said another end side of the first supporting member and to support an RF coil unit installed at an inner side of the gradient magnetic field coil unit in a vertical direction by being made in contact with the RF coil unit.

5. The gradient coil supporting implement according to claim 4,
wherein the third supporting member includes a vibration-proof member fixed to a side of the RF coil unit.

6. The gradient coil supporting implement according to claim 4,
wherein the mounting main body has line symmetrical structure.

7. The gradient coil supporting implement according to claim 4,
wherein at least a part of each of the three bearings is formed of an insulator to insulate between the static magnetic field magnet and the mounting main body.

8. The gradient coil supporting implement according to claim 1,
wherein all of the three bearings are spherical bearings.

9. The gradient coil supporting implement according to claim 8,
wherein at least a part of each of the three bearings is formed of an insulator to insulate between the static magnetic field magnet and the mounting main body.

10. The gradient coil supporting implement according to claim 1,
wherein the mounting main body has line symmetrical structure.

11. The gradient coil supporting implement according to claim 1,
wherein at least a part of each of the three bearings is formed of an insulator to insulate between the static magnetic field magnet and the mounting main body.

12. The gradient coil supporting implement according to claim 2,
wherein the mounting main body further includes a third supporting member configured to be fixed to said another end side of the first supporting member and to support an RF coil unit installed at an inner side of the gradient magnetic field coil unit in a vertical direction by being made contact with the RF coil unit.

13. A magnetic resonance imaging apparatus comprising:
a static magnetic field magnet configured to apply a static magnetic field to an imaging space;
a gradient magnetic field coil unit installed at an inner side of the static magnetic field magnet and configured to apply a gradient magnetic field to an imaging region;
the gradient coil supporting implement according to claim 1 configured to support the gradient magnetic field coil unit;
an RF coil unit configured to transmit an RF pulse for causing nuclear magnetic resonance to the imaging region; and
a control device configured to perform a pulse sequence, in which MR signals from an object in the imaging region are acquired, by controlling the gradient magnetic field coil unit and the RF coil unit, and to reconstruct image data based on the MR signals.
